(19) United States
(12) Patent Application Publication
(10) Pub. No.: US 2026/0287613 A1
(43) Pub. Date: Sep. 24, 2026

(54) Socketed Probes

(71) Applicant: Translarity, Inc., Fremont, CA (US)

(72) Inventor: Raul Molina, Austin, TX (US)

(21) Appl. No.: 19/340,704

(22) Filed: Sep. 25, 2025

Related U.S. Application Data
(63) Continuation-in-part of application No. 18/223,698, filed on Jul. 19, 2023, now Pat. No. 12,601,758.
Application No. 18/223,698 is a continuation of application No. 17/967,857, filed on Dec. 8, 2023, now abandoned.
(60) Provisional application No. 63/256,439, filed on Oct. 15, 2021.
(60) Provisional application No. 63/279,699, filed on Nov. 16, 2021.
(60) Provisional application No. 63/699,071, filed on Sep. 25, 2024.
(60) Provisional application No. 63/699,098, filed on Sep. 25, 2024.

(51) Int. Cl. G01R 1/04; G01R 1/067

(52) U.S. Cl. CPC G01R 1/0441; G01R 1/06722; G01R 1/06727

(57) ABSTRACT

A modular/configurable space transformer system may comprise socketed probes, an upper guide plate, a lower guide plate, and a spacer. A socketed probe may comprise an upper support arm with positioning tabs for insertion into slots in the upper guide plate, as well as a PCB contact point for making a conductive connection with a PCB pad. The socketed probe may additionally comprise a lower support arm with a positioning tab for insertion into a slot in an upper guide plate, as well as a DUT (device under testing) contact point for making a conductive connection with a DUT pad. The spacer may separate the upper guide plate and lower guide plate. The upper support arm may comprise two separate components configured to be electrically connected through a trade on the upper guide plate.

### CROSS REFERENCE TO CORRELATED APPLICATIONS

This application is a continuation-in-part of U.S. patent application Ser. No. 18/223,698 (titled “Socketed Probes,” filed on Jul. 19, 2023, the first inventor of which is Raul Molina), which is a continuation of U.S. patent application Ser. No. 17/967,857 (titled “Socketed Probes,” filed on Oct. 17, 2022), the first inventor of which is Raul Molina). patent application Ser. No. 17/967,857 claims the benefit of U.S. provisional application nos. (i) 63/256,493 (titled “Socketed Probes,” filed on Oct. 15, 2021, and the first inventor of which is Raul Molina) and (ii) 63/279,699 (titled “Socketed Probes,” filed on Nov. 16, 2021, and the first inventor of which is Raul Molina).

This application additionally claims the benefit of U.S. provisional application nos. (i) 63/699,071 (titled “Socketed Probes,” filed on Sep. 25, 2024, and the first inventor of which is Raul Molina) and (ii) 63/699,098 (titled “Socketed Probes, filed on Sep. 25, 2024, and the first inventor of which is Raul Molina).

These applications are incorporated herein by reference in their respective entireties.

### BACKGROUND OF THE INVENTION

A space transformer is used in integrated circuit testing as an adapter or transition between the spatially dense test pads on a device under testing (DUT) and the less dense probe pads on the testing printed circuit board (PCB). In informal terms, a space transformer “fans” out the spatially dense test outputs from the DUT into a manageable and less spatially dense set of test pads for input into a testing PCB. Or, in other words, a space transformer translates wafer-level pad pitch and feature dimensions to a larger pad pitch and/or feature dimensions-usually that of a testing PCB.

One of the problems with space transformers is that they can be expensive to design and manufacture, often requiring a customized solution for each DUT and/or PCB.

What is needed is a space translator solution that is less expensive, more modular, and more adaptable.

### BRIEF SUMMARY OF THE INVENTION

A modular/configurable space transformer system may comprise socketed probes, an upper guide plate, a lower guide plate, and a spacer. A socketed probe may comprise an upper support arm with positioning tabs for insertion into slots in the upper guide plate, as well as a PCB contact point for making a conductive connection with a PCB pad. The socketed probe may additionally comprise a lower support arm with a positioning tab for insertion into a slot in an upper guide plate, as well as a DUT (device under testing) contact point for making a conductive connection with a DUT pad. The spacer may separate the upper guide plate and lower guide plate.

### BRIEF DESCRIPTION OF THE DRAWINGS

FIG. 1 is a side view of an exemplary socketed probe.

FIG. 2 is an elevated-angle view of an exemplary socketed probe.

FIG. 3 is a side view of an exemplary socketed probe, along with PCB, upper guide plate, spacer, lower guide plate, and DUT.

FIG. 4A is a top-down view of a PCB in which the six dashed circles represent testing PCB pads located on the underside of the PCB.

FIG. 4B is a top-down view of an upper guide plate.

FIG. 4C is a top-down view of a lower guide plate.

FIG. 4D is a top-down view of an exemplary DUT.

FIG. 5 is an elevated-angle sectional view of an exemplary testing assembly.

FIG. 6 is an elevated-angle sectional view of an exemplary testing assembly in which the upper guide plate is visible.

FIG. 7 is an elevated-angle partially exploded view of an exemplary testing assembly.

FIG. 8 is a lower-angle perspective sectional view of an exemplary testing assembly.

FIG. 9 is a lower-angle fully exploded view of an exemplary testing assembly.

FIG. 10 is a lower-angle partially exploded view of an exemplary testing assembly.

FIG. 11 is a lower angle view of space transformer system 100 without some parts of the lower guide plate and without the DUT.

FIG. 12 is a lower angle view of space transformer system 100 without some parts of the lower guide plate and without the DUT.

FIG. 13 is an exploded lower angle view of space transformer system 100 with a one-quarter cutaway of the assembly comprising the lower guide plate, spacer, upper guide plate, and associated socketed probes.

FIG. 14 is an exploded lower angle view of space transformer system 100 with a one-quarter cutaway of the assembly comprising the lower guide plate, spacer, upper guide plate, and associated socketed probes-except for the upper guide plate, and having only two socketed probes.

FIG. 15 is an exploded lower angle view of space transformer system 100—without the lower guide plate and DUT, and having only two socketed probes.

FIG. 16 is a side view of the upper end of an exemplary socketed probe having exemplary dimensions.

FIG. 17 is a side view of the lower end of an exemplary socketed probe having exemplary dimensions.

FIGS. 18A-C show insertion of an exemplary socketed probe into an upper guide plate.

FIGS. 19A-B show the scrubbing motion on a device under testing.

FIG. 20 is a cross-section view of an exemplary testing assembly that illustrates the use of multiple socketed probes with varying upper horizontal support arm lengths within a testing assembly.

FIGS. 21A and 21B show alternative embodiment in which a socketed probe may be divided into two components.

FIGS. 22A, 22B, and 23 show additional views of the embodiment in which a socketed probe may be divided into two components.

FIG. 24 shows a top-down view of an exemplary implementation in which a socketed probe may be divided into two components.

FIGS. 25A and 25B show two different views of the an implementation using two split probes as described herein.

FIGS. 26 and 27 show an exemplary alternative design for a socketed probe.

FIGS. 28A-D shows four variations of a socketed probe in which the distal end offset is different in each variant.

FIG. 29 shows an implementation using eight probes, some of which have varying distal end offsets.

FIGS. 30A-C FIG. 30 shows four probes having varying distal end offsets in an upper guide plate.

FIGS. 31A-C show additional views of an exemplary implementation of the probes shown in FIGS. 26, 27, and 28A-D.

FIG. 32 shows a top-down view of upper guide plate holes in an exemplary embodiment.

FIG. 33 shows a close-up side view of four probes (e.g., the probes shown in FIGS. 26, 27, and 28A-D), each having different distal offsets, seated in the upper guide plate.

FIG. 34 shows a close-up side view of four probes (e.g., the probes shown in FIGS. 26, 27, and 28A-D) seated in the lower guide plate.

### DETAILED DESCRIPTION OF THE INVENTION

A system and method are disclosed for a socketed probe and for a modular and

adaptable space transformer system.

### Table of Reference Numbers from Drawings

The following table is for convenience only and should not be construed to supersede any potentially inconsistent disclosure herein.

| Reference | |
|---|---|
| Number | Description |
| 100 | space transformer system |
| 110 | upper guide plate |
| 112a-n | slots in upper guide plate 110 for |
| | rough positioning tab 230 |
| 114a-n | slots in upper guide plate 110 for |
| | fine positioning tab 240 |
| 115a-n | Positioning walls in slots 114a-n |
| 120 | lower guide plate |
| 122a-n | slots in lower guide plate 120 for |
| | lower fine-positioning tab 270 |
| 130 | spacer |
| 200 | socketed probe |
| 203 | Cantilever spring arm assembly |
| 205 | PCB contact |
| 207 | PCB contact point arm |
| 210 | PCB cantilever spring arm |
| 212 | PCB contact support arm |
| 222 | spring-bend cutout |
| 220 | Upper handling tab |
| 225 | Upper horizontal support arm |
| 230 | rough positioning tab |
| 231 | Pointed/tapered end of rough |
| | positioning tab |
| 232 | Corner cutout |
| 234 | Corner cutout |
| 236 | Corner cutout |
| 240 | Fine positioning tab |
| 241 | position-set edge of fine |
| | positioning tab 240 |
| 242 | fine position spring arm |
| 243 | Spring arm inflection point |
| 244 | Compression spacing |
| 250 | Connector arm |
| 255 | DUT contact |
| 257 | DUT contact point arm |
| 270 | Lower fine-positioning tab |
| 271 | position-set edge of lower |
| | fine positioning tab 270 |
| 272 | Lower fine-positioning spring arm |
| 273 | Compression space |
| 274 | Spring arm contact edge |
| 275a-b | Lower horizontal support arm |
| 276 | Spring arm inflection point |
| 290 | Lower handling tab |
| 300a-n | socketed probes |
| 330a-n | Rough positioning tabs for socketed |
| | probes 300a-n, respectively |
| 340a-n | Fine positioning tabs for socketed |
| | probes 300a-n, respectively |
| 600 | testing PCB |
| 610a-n | testing PCB pads |
| 700 | device under testing (“DUT”) |
| 710a-n | DUT pads |
| 800a | core component of split socketed probe |
| 800b | core component of split socketed probe |
| 803 | Cantilever spring arm assembly |
| 805 | PCB contact |
| 807 | PCB contact point arm |
| 810 | PCB cantilever spring arm |
| 812 | PCB contact support arm |
| 825 | Upper horizontal support arm |
| 834 | Corner cutout |
| 840 | Fine positioning tab |
| 841 | position-set edge of fine positioning tab 240 |
| 842 | fine position spring arm |
| 843 | Spring arm inflection point |
| 855 | Connector arm |
| 857 | DUT contact |
| 870 | DUT contact point arm |
| 875a-b | Lower horizontal support arm |
| 891 | Corner cutout |
| 892 | Fine positioning tab |
| 893 | position-set edge of fine positioning tab 240 |
| 894 | fine position spring arm |
| 895 | Spring arm inflection point |
| 910 | upper guide plate |
| 915 | trace on upper guide plate |
| 920 | lower guide plate |
| 924a-b | split probe |
| 925a-b | split probe |
| 926 | trace |
| 927 | trace |
| 950 | upper guide plates |
| 955 | “fanned-out” parts of split probes in upper guide plate |
| 960 | non-“fanned-out” parts of split probes in |
| | upper guide plate |
| 965 | parts of probes in lower guide plate |
| 970 | traces |
| 1100 | space transformer system |
| 1110 | probe |
| 1112 | probes |
| 1115 | PCB contact |
| 1120 | upper first positioning tab |
| 1130 | upper second positining tab |
| 1150 | DUT probe guard |
| 1170 | DUT probe arm |
| 1171 | hole in lower guide plate for DUT probe arm |
| 1180 | upper guide plate |
| 1182 | upper guide plate holes for upper first positioning |
| | tabs (1120) |
| 1184 | upper guide plate holes for upper second positioning |
| | tabs (1130) |
| 1190 | lower guide plate |
| 1192 | lower guide plate holes for DUT probe arms (1170) |
| 1601 | A width measurement of PCB cantilever spring arm |
| 1602 | A width measurement of PCB cantilever spring arm |
| 1603 | A width measurement of PCB contact support arm |
| 1604 | A width measurement of PCB contact point arm |
| 1605 | A height measurement of PCB cantilever spring arm |
| 1606 | A height measurement of upper horizontal support arm |
| 1607 | A height measurement of upper fine positioning tab |
| 1608 | A width measurement of upper fine positioning tab |
| 1609 | A width measurement of upper rough positioning tab |
| 1610 | A height measurement of upper rough positioning tab |
| 1611 | A height measurement of PCB cantilever spring arm |
| 1701 | A width measurement of lower handling tab |
| 1702 | A height measurement of lower handing tab |
| 1703 | A height measurement of a lower horizontal support arm |
| 1704 | A height measurement of a lower horizontal support arm |
| 1705 | A width measurement of DUT contact point arm |
| 1706 | A width measurement of the edge of the lower rough |
| | positioning tab to the DUT contact point arm edge |
| 1707 | A width measurement of the lower rough positioning tab |
| 1708 | A width measurement of the lower fine positioning spring |
| | arm |
| 1709 | A width measurement of the lower fine positioning tab |
| 1710 | A height measurement of the lower positing tab |
| 1711 | An angle measurement of the top of the lower horizontal |
| | support arm to the DUT contact point arm |
| 1800a-n | Socketed probes with varying horizontal offsets |

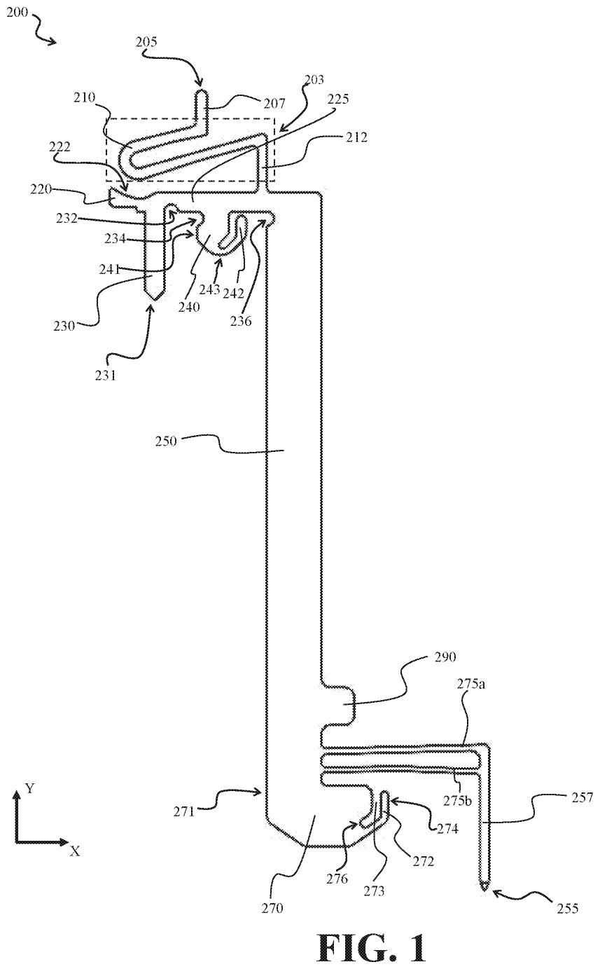

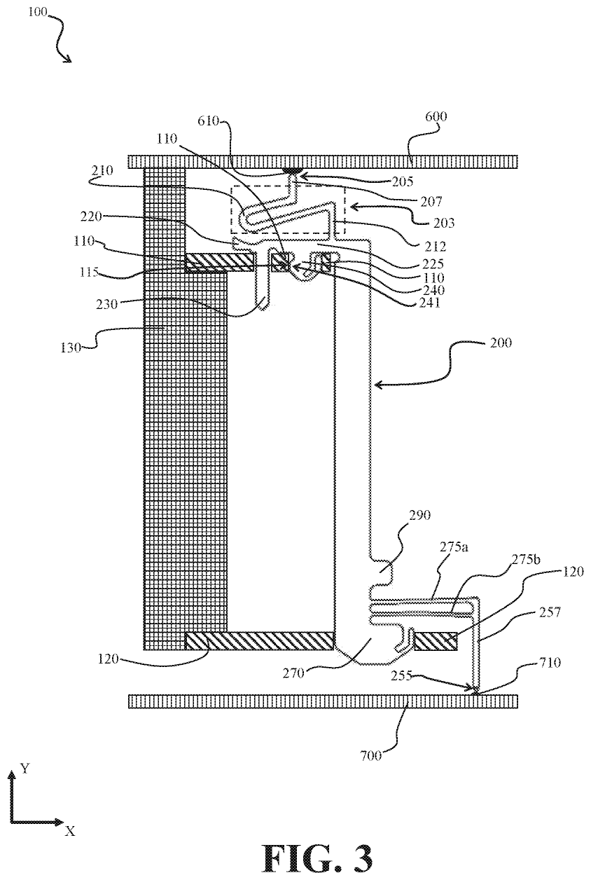

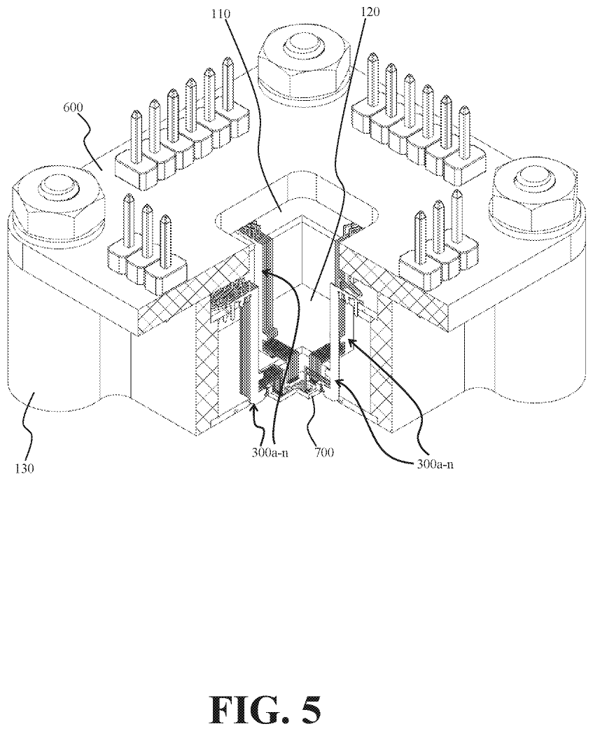

As shown in FIGS. 3 and 5-15, a space transformer system 100 may comprise an upper guide plate 110, lower guide plate 120, and at least one socketed probe 200. FIGS. 1-3 and 16-19 reference and illustrate a single socketed probe 200. FIGS. 5-15 and 20 reference and illustrate a set of socketed probes 300a-n within a testing system. A testing printed circuit board (“PCB”) 600 and device under testing (“DUT”) 700 are also shown in some of FIGS. 3, 5-15, 19, and 20.

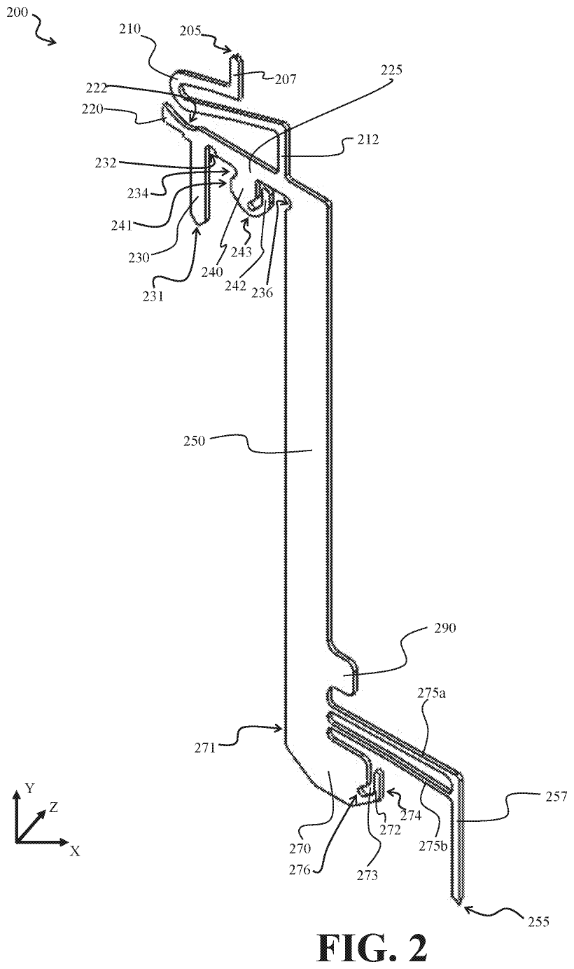

As shown in detail FIGS. 1-3, a socketed probe 200 may have several features. FIG. 1 shows a side view of an exemplary socketed probe 200. FIG. 2 shows an elevated-angle perspective of an exemplary socketed probe 200. FIG. 3 shows a side view of an exemplary socketed probe 200, along with PCB 600, upper guide plate 110, spacer 130, lower guide plate 120, and DUT 700.

### Upper Assembly

As shown at least in FIGS. 1-3, 16, and 18A-C upper horizontal support arm 225 may be an arm extending horizontally from connector arm 250 to support PCB contact support arm 212 (which supports PCB cantilever spring arm 210 and PCB contact point arm 207), fine positioning tab 240, rough positioning tab 230, and handling tab 220.

In one embodiment, horizontal arm 225 may have the geometry as shown in FIG. 1. The dimensions of horizontal arm 225 may be adjusted based on the dimensionss of space transformer system 100, other components of space transformer system 100, problem domain parameters (e.g., size of DUT, size of PCB, etc.), or other factors. In one embodiment, horizontal arm 225 may have sufficient height to maintain sufficient y-dimension rigidity; and sufficient extension from connector arm 250 to provide a connection point for PCB contact support arm 212, fine positioning tab 240, rough positioning tab 230, and handling tab 220.

The purpose/function of spring arm assembly 203 (components 205, 207, 210, and 212) is to provide a contact point for testing PCB pad 610 that is able to move in the y-dimension (i.e., up and down as shown in FIGS. 1 and 3), exert upward pressure toward testing PCB pad 610 to maintain contact with testing PCB pad 610, and minimize movement in the x-dimension (i.e., left and right as shown in FIGS. 1 and 3) so that PCB contact point 205 maintains contact with testing PCB pad 610. The length of PCB contact support arm 212 may be modified based on the characteristics of a particular application. In general, support arm 212 may be sufficiently long/high so that PCB cantilever spring arm 210, when flexed downward toward upper horizontal support arm 225, does not come in contact with upper horizontal support arm 225. Although such contact would likely not compromise the conductivity characteristics of socketed probe 200, such contact may result in undesirable x-dimension dislocation of PCB contact 205, and may additionally prevent contact points on other socketed probes from properly contacting their respective testing PCB pads.

PCB cantilever spring arm 210 may have a curvature, angle (relative to PCB contact support arm 212), and length/dimensions designed to minimize x-dimension displacement of contact 205 when contact 205 is subject to downward (y-dimension) pressure, e.g., from interaction with testing PCB pad 610. Such downward pressure may frequently result in y-dimension displacement of contact 205. In general, the concept of a cantilever spring is known in the art. The dimensions, shape, and geometries of cantilever spring art 210 may be adjusted and/or modified without departing from the scope of this disclosure. In one embodiment, spring arm 210 may have the geometry shown in FIG. 1. In general, increasing the length of spring arm 210 may decrease the potential for x-dimension displacement from downward pressure on contact point 205. As shown in FIGS. 1 and 3, for practical reasons the curve on spring arm 210 may extend (to the left as shown in FIGS. 1 and 3) to approximately the same x location as the left edge of handling tab 220. The dimensions, shape, and geometries of cantilever spring arm assembly (comprising PCB contact support arm 212, PCB cantilever spring arm 210, PCB contact point arm 207, and PCB contact 205) may be adjusted, modified, and/or tuned to change x-dimension displacement and sensitivity characteristics, y-dimension displacement and sensitivity characteristics, and other characteristics of cantilever spring arm assembly—without departing from the scope of this disclosure.

PCB spring arm 210 may be designed so that, when compressed, i.e., when applied to testing PCB pad 610, PCB contact 210 maintains its x-position (right-left in FIGS. 1 and 3) even while its y-position (up-down in FIGS. 1 and 3) changes as a result of the compression resulting from pressure from testing PCB pad 610.

PCB contact point arm 207 may transition out of spring arm 210 in a vertical, or a substantially vertical, orientation. As described above, cantilever spring arm assembly 203 may have various dimensions, shapes, and geometries. In some embodiments, PCB contact point arm 207 may be shorter, longer, or relatively non-existent as compared to the exemplary drawings. In general, the design-including but not limited to shapes, geometries, and dimensions—of cantilever spring arm assembly 203 may have several benefits: ensuring (or decreasing the likelihood) that testing PCB 600 does not come in contact with the highest point (or any point) of PCB contact support arm 212; preventing (or decreasing the likelihood of) PCB cantilever spring arm 210 becoming horizontal (or going past horizontal) and contacting testing PCB 600 at a location other than testing PCB pad 610; providing particle tolerance robustness, i.e., increasing the minimum size of a foreign particle/debris that could be problematic if the foreign particle debris was between testing PCB 600 and PCB cantilever spring arm 210 such that it contacted both testing PCB 600 and PCB cantilever spring arm 210 and created/forced a gap that prevented PCB contact 205 from touching PCB testing pad 610. In general, height/length of PCB contact point arm 207 may depend on multiple characteristics, e.g., potential flex of spring arm 210 and resulting downward displacement of contact point 205, and anticipated distance to relative placement of testing PCB 600.

Rough positioning tab 230 may have several purposes. As shown in FIG. 2, rough positioning tab 230 may protrude downward (in the y-direction) further than fine positioning tab 240, and, when socketed probe 200 is being inserted downward into upper guide plate 110 (as described herein below), will therefore engage upper guide plate 110 before fine positioning tab 240 engages upper guide plate 110. Pointed/tapered tip 231 will facilitate easy insertion tab 230 into upper guide plate 110 (as described herein below). Even if tab 230 is slightly misaligned relative to the matching slot/hole in upper guide plate 110 in the x-dimension, pointed/tapered tip 231 will facilitate alignment as tab 230 is inserted into a slot/hole in upper guide plate 110.

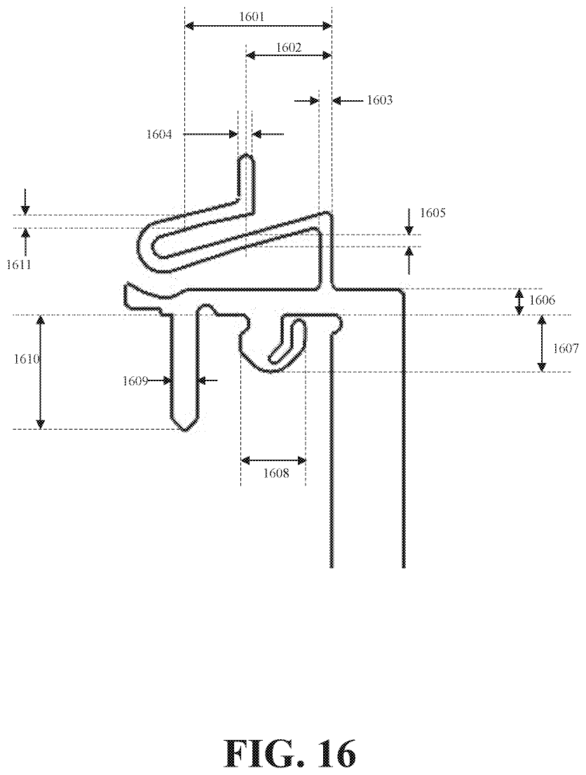

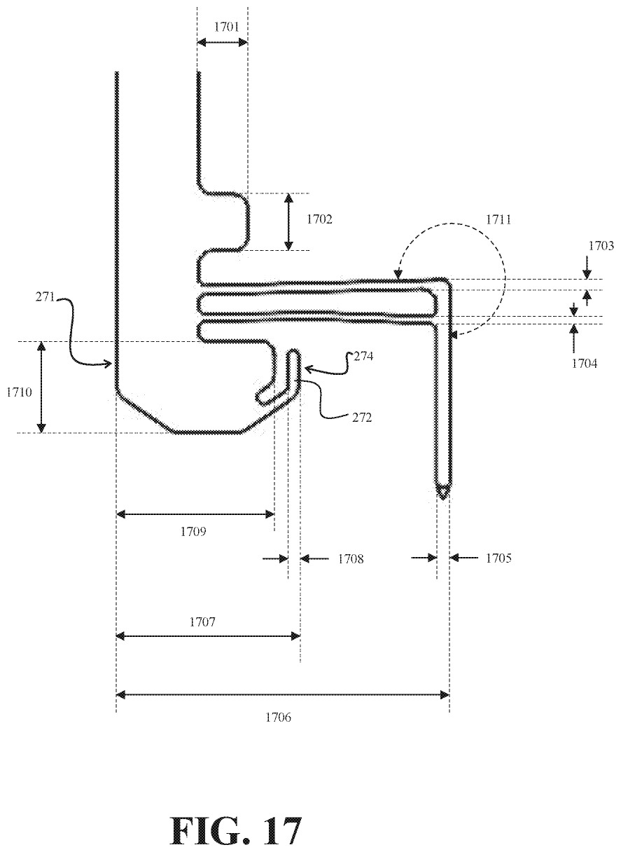

As shown in FIGS. 1-15, and having exemplary dimensions as shown in FIGS. 16 and 17, the heights/lengths (i.e., y-dimension length), of tabs 230, 240, and 270 may be different relative to the respective insertion points into upper guide plate 110 (for tabs 230 and 240, which are inserted in slots 112 and 114, respectively) and lower guide plate 120 (for tab 270, which is inserted in slot 122), such that the tabs are inserted into their respective slots in a distinct sequence/order. It may be beneficial to use varying slot lengths to compel/require an insertion order/sequence so that the operator or other entity, machine, or actor doing the insertion has only one target to hit at a time, and subtle movements to insert subsequent tabs will not fully or partially unseat the previously inserted tabs. Although varied tab lengths and insertion order may have the benefits described above, and/or other benefits, this feature is not strictly required or necessary.

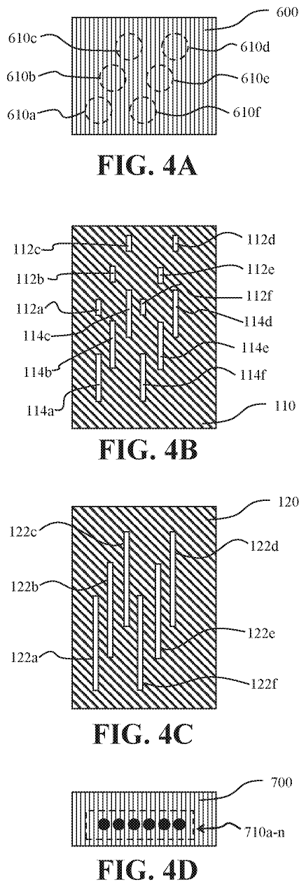

In general, the dimensions of rough positioning tab 230 may be the same as or slightly less than the associated dimensions of complementary slots 112a-n, which are shown at least in FIGS. 4B, 6-7, 9-10, 13-15, and 18A-C. For example, width 1609 (FIG. 16) rough positioning tab 230 may be between 100 and 500 μm, and the thickness may be 50 μm. The corresponding dimension of slot 112 may be 3-10 μm greater than the thickness of rough positioning tab 230. So, if rough positioning tab 230 has a thickness of 50 μm, the corresponding dimension of slot 112 may be 53-60 μm. In one embodiment, the width 1609 of tab 230 may be 200 μm. In this embodiment, the corresponding dimension of slot 112 may be 10-30 μm greater than the width 1609 of tab 230, i.e., may be 210-230 μm. Similar principles apply to the thickness (but not the width, as explained below) of tabs 240 and 270.

For fine-positioning tabs 240 and 270, the corresponding width dimensions for slots 114 and 122, respectively, may be slightly smaller than the uncompressed width dimensions 1608 and 1707 for tabs 240 and 270, respectively. By making the widths of slots 114 and 122 slightly smaller that the uncompressed widths 1608 and 1707 of tabs 240 and 270, respectively, tabs 240 and 270 will compress upon insertion into slots 114 and 122, respectively.

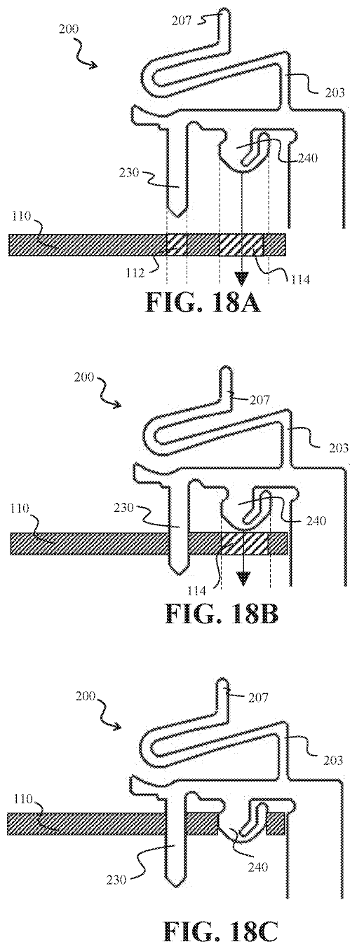

An exemplary insertion of the upper tabs is illustrated in FIGS. 18A-C. As shown in FIG. 18A, the width of slot 114 may be slightly less than width 1608 of upper fine positioning tab 240. As shown in FIG. 18B, as socketed probe 200 is inserted into upper guide plate 110, rough positioning tab 230 will be inserted into upper guide plate 110 before fine positioning tab 240 is inserted into upper guide plate 110. As shown in FIGS. 18B and 18C, fine positioning tab 240 will compress during the insertion process, thereby ensuring that the left edge of fine positioning tab 240 is aligned with the left edge of slot 114. FIGS. 18A-C are not meant to show precise locations and/or dimensions, but merely to provide a conceptual view of an exemplary system. Lower fine positioning tab 270 is configured to behave similarly to upper fine positioning tab 240.

To reiterate as already explained herein: The dimensions of tabs 230, 240, and 270 may vary widely depending on constraints of a particular application or problem domain. Although the respective slots 112, 114, and 122 could have the same dimensions as tabs 230, 240 (in fully compressed state), and 270 (in fully compressed state), for practical reasons it may be beneficial to make the dimensions of slots 112, 114, and 122 slightly greater than the corresponding dimensions of tabs 230, 240 (in fully compressed state), and 270 (in fully compressed state), respectively.

The main purpose of fine positioning tab 240 is to secure socketed probe 200 at a known, certain, and stable x-dimension location. As shown in FIGS. 1-2, the uncompressed width of tab 240—from left edge 241 to the right (far) edge of spring arm 242—may be slightly greater than the width of associated guide slot 114 in upper guide plate 110. The fully compressed width of tab 240 may be equal to or slightly less than slightly less than the width of associated guide slot 114 in upper guide plate 110. The spring arm design of tab 240 (including spring arm 242), will result in pressing edge 241 of tab 240 against wall 115 of guide slot 114 in upper guide plate 110, thereby ensuring a predictable and stable x-dimension position of socketed probe 200 relative to upper guide plate 110. In general, inflection point 243 may be sufficiently skinny to allow spring arm 242 to bend toward edge 241 when pressure is applied, e.g., from wall 115 of slot 114 in upper guide plate 110. This design ensures that edge 241 is flush with and in contact with wall 115 of guide slot 114 in upper guide plate 110.

Corner cutouts 232, 234, and 236, which are shown and marked in FIGS. 1-2, are not strictly necessary, but are a practical feature to mitigate the likelihood of the undesirable results of imperfect 90-degree corners in the manufacturing process, which imperfect corners could result in improper positioning of socketed probe 200.

Handling tab 220 is for convenience in manufacturing, handling, manipulating, placing, orienting, and moving socketed probe 200. For example, handling tab 220 may be used for grasping by fingers, pliers, or another tool.

Spring-bend cutout 222 allows for downward displacement of spring arm 210 without coming into contact with horizontal support arm 225.

The length of connector arm 250 may vary depending on the dimensions of spacer 130 and other dimensions of a particular embodiment or application.

### Lower Assembly

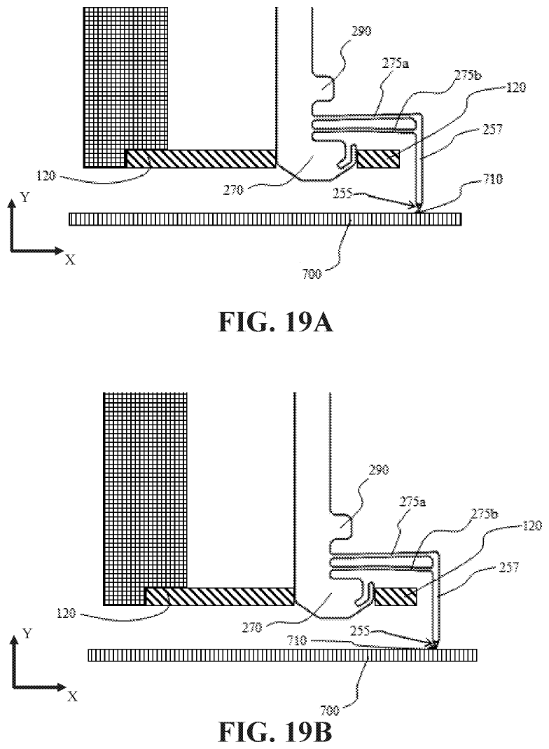

Although the disclosure herein shows rough positioning tab 230 as being a part of and/or connected to upper horizontal support arm 225, and being designed to engage upper guide plate 110, in an alternative embodiment a rough positioning tab may be designed to engage lower guide plate 120. Although this approach is feasible, it may have several drawbacks. First, it may be more difficult to insert a rough positioning tab 230 into the lower guide plate 120 because the corresponding slot in the lower guide plate 120 may be visually obscured in whole or in part. Additionally, depending on the length of the rough positioning tab 230, a rough positioning tab 230 that engages the lower guide plate 120 may protrude, e.g., a few hundred microns, toward the DUT surface 700, thereby reducing the effective extension of DUT contact point arm 257. Increasing the length of DUT contact point arm 257 to offset this reduced effective extension may compromise the characteristics of DUT contact point arm 257, e.g., reducing its stiffness and ability to scrub laterally, i.e., to scrape across the surface of DUT pad 710 and “dig in,” as shown in FIG. 19a-b.

As shown in FIGS. 1-3, lower fine-positioning tab 270 (including edge 271 and spring arm 272) positions DUT contact 255 in the x-dimension relative to lower guide plate 120. In one embodiment, x-dimension 1707 from left edge 271 of lower fine-positioning tab 270 to right edge of uncompressed spring arm 272 may be slightly greater than the width of slot 122 in lower guide plate 120, so that spring arm 272 is compressed toward edge 271 when tab 270 is inserted into slot 122 in lower guide plate 120, and edge 271 and right edge of spring arm 272 thereby engage walls of slot 122, respectively. In this manner, edge 271 is pressed into position against the interior walls of slot 122 so that it is flush against wall the opposing interior wall of slot 122, thereby ensuring a predictable and stable x-dimension position for contact point 255 relative to lower guide plate 120.

Support arm 275a-b supports contact arm 257 and associated contact point 255. In one embodiment, as shown in FIGS. 1-3, support arm 275a-b may comprise a two-arm design comprising a top arm 275a that is substantially straight and a bottom arm 275b that is slightly curved.

As shown in FIGS. 19A-B, the mismatched lengths of 275a and 275b, along with the curvature on bottom arm 275b result in a tendency for contact point 255 to “scrub” DUT pad 710, i.e., to scrape across the surface of DUT pad 710 and “dig in.” This phenomenon may be beneficial because it allows contact point 255 to come in contact with fresh and clean conductive material in DUT pad 710, instead of being in contact with potentially deteriorated or dirty surface material on DUT pad 710. The two-arm design allows contact point 255 to maintain the same z-dimension, i.e., in and out of the direct profile drawing in FIG. 17, and to remain aligned in the z-dimension with DUT pad 710, while changing the angle of arm 257 relative to lower guide plate 120 and, correspondingly, changing the x-dimension of contact point 255. This x-dimension movement contact point 255 along DUT testing pad 710 may be referred to as “scrub.”

Handling tab 290 is for convenience in manufacturing, handling, manipulating, placing, orienting, and moving socketed probe 200. For example, handling tab 290 may be used for grasping by fingers, pliers, or another tool. Alternatively, handling tab 290 may be used as a push point for pushing socketed probe 200 into lower guide plate 120.

The dimensions and geometry of the two-bar design may be adjusted to account for different applications and domain-specific needs/requirements.

Socketed probe 200 may be made out of various materials or combinations of materials. In a preferred embodiment, socketed probe 200 is monolithic. In general, the material(s) from which socketed probe 200 is made will have several characteristics: electrically conductive and substantially rigid (but bendable where the material is thin enough, as described herein). Feasible materials for socketed probe 200 may include, but are not limited to, C17200 BeCu, C17500 BeCu, Deringer Ney materials (H3C, P7, P25, etc), AgCu alloy, and other materials or combinations of materials as may be known in the art.

### Spacer

As shown in FIG. 3, upper guide plate 110 may be connected/secured to lower guide plate 120 by a structure/component that may be referred to as a “spacer” 130. The spacer may be any apparatus, device, hardware, or system that maintains upper guide plate 110 and lower guide plate 120 in orientations and positions relative to each other so that upper guide plate 110 is substantially parallel with lower guide plate 120 and the position of upper guide plate 110 is fixed relative to the position of lower guide plate 120.

The position of DUT 700 relative to lower guide plate 120 may be maintained in several ways. In one embodiment, DUT 700 may be on or secured to a movable chuck that may align DUT 700 and, consequently, DUT contact pad 710, with lower guide plate 120. The chuck may move upward to probe tip 255 and establish contact between probe tip 255 and contact pad 710. In other embodiments, other hardware, machinery, or otherwise may be used to set or maintain the spatial relationship between DUT 700 and lower guide plate 120.

### Upper Guide Plate

As shown in FIG. 4B, which is a top-down view of a portion of exemplary upper guide plate 110, upper guide plate 110 may be a device having guide slots for insertion of tabs 230 and 240 from socketed probe 200. In one embodiment, the portions of upper guide plate 110 that come in contact with socketed probe 200 may be substantially flat so that the portions of socketed probe 200 that come in contact with upper guide plate 110 are flush with surface(s) of upper guide plate 110, or at least rest against upper guide plate 110 in a stable and secure manner. It may be possible to use an upper guide plate that is not flat for contact with a socketed probe, but this approach may give rise to unnecessary difficulties and design complexities.

In one embodiment, upper guide plate 110 may be a flat device, e.g., as shown in FIG. 4B, with slots dimensioned for insertion of tabs 230 and 240 of socketed probe 200. For example, in one embodiment socketed probe 200 may be made of beryllium copper that is 50 μm (micrometers) thick. In this embodiment, slots 112a-n and 114a-n in upper guide plate 110 may be 48 μm wide so that tabs 230 and 240 fit comfortably and snugly in slots 112 and 114 respectively.

In one embodiment, tab 230 may be 200 μm wide and tab 240 may be, uncompressed, 530 μm wide. For these dimensions, slot 112 for tab 230 may be 220 μm long and slot 114 for tab 240 may be 510 μm long. In one embodiment, thickness of upper guide plate 110 may be 600 μm.

In one embodiment, upper guide plate 110 and lower guide plate 120 may be made from silicon nitride. Many non-conductive materials are known in the art and may be used for upper guide plate 110 and lower guide plate 120.

### Lower Guide Plate

Lower guide plate 120 is similar to upper guide plate 110, except that slot 122 in lower guide plate 120 is dimensioned to accommodate tab 270 of socketed probe 200. In one embodiment in tab 270 may be 1,290 μm wide uncompressed, and may be 1,270 μm wide in a fully compressed state. For these dimensions, slot 122 for tab 270 may be 1,275 μm long. In one embodiment, thickness of lower guide plate 120 may be 400 μm.

FIGS. 4A-C show top-down views of an exemplary PCB 600, upper guide plate 110, lower guide plate 120, and DUT 700, respectively. FIGS. 4A-C are not meant to show precise locations and/or dimensions, but merely to provide a conceptual view of an exemplary system comprising PCB 600, upper guide plate 110, lower guide plate 120, and DUT 700, respectively.

FIG. 4A shows a top-down view of a PCB 600. The six dashed circles represent testing PCB pads 610a-n. They are dashed because they are on the bottom of PCB 600 are therefore not visible in a top-down view.

FIG. 4B shows a top-down view of an upper guide plate 110. Rough-positioning slots 114a-n and fine positioning slots 112a-n correspond to testing PCB pads 610a-n, respectively.

FIG. 4C shows a top-down view of a lower guide plate 120. Fine positioning slots 122a-n correspond to slots 114a-n and 112-a-n, respectively, in upper guide plate 110.

FIG. 4D shows a top-down view of exemplary DUT 700. DUT pads 710a-n correspond to testing PCB pads 610a-n, slots 114a-n and 112-a-n on upper guide plate 110, and slots 122a-n on lower guide plate 120.

### Fabrication

Many technologies, machines, and/or processes may be used to fabricate socketed probes as described herein. For example, a socketed probe may be fabricated by laser cutting from metal foil; etching from metal foil; stamping/forming;

MEMS/electroplating/electroforming; combinations of one or more of these approaches; and/or other technologies and/or methods that may be known in the art.

Laser cutting from metal foil may comprise subtractive processing beginning with a thin metal foil and using a laser to cut one or more probes out of that foil. This technology is well-known. Achieving the required tolerances and dimensions may require a high-end laser system.

Etching from metal foil may comprise subtractive processing beginning with a thin metal foil and using masking and chemical etching to release/cut one or more probes out of the foil.

Stamping/forming may be used to manufacture a probe by beginning with a wire, strip, or foil and smashing, stretching, and/or cutting a probe into its final geometry.

MEMS/electroplating/electroforming is an additive manufacturing technology in which metal is grown on a substrate in specific/desired areas using masking.

Combinations of the above methods may include, but are not limited to: plating metals to form a foil and then etching or laser-cutting to form a probe; stamping, etching, or laser-cutting to form probes and then plating metal on the formed geometry.

In one embodiment the probed socket 200 is one with uniform thickness. An advantage of a probed socket 200 with uniform thickness is the efficiency and ease of manufacture. However, a socketed probe 200 could have a non-uniform thickness, e.g., the upper handling tab 220, upper rough positioning tab 230, and upper fine positioning tab 240 are of one consistent thickness and the connector arm 250 tapers to a thinner thickness for the lower handling tab 290, lower horizontal support arm 275a-b, DTU contact point arm 257 to better accommodate the dimensions of DTU 700.

In another embodiment of non-uniform thickness the connecting arm 250 may be thinner than the upper end and lower end of the socketed probe 200. The thinner connecting arm 250 may then be bent to a desired shape after manufacturing but prior to the installation in the testing system. The thinner connecting arm 250 allows for ease of efficient manufacturing while allowing for later modifications of the design for proper fit within a testing system.

In one embodiment of a system as disclosed herein, socketed probes 300a-n have varying dimensions. The dimensions of socketed probe 200 may be modified for varying DUT pads 710a-n. For example, socket probes 300a-d may have a longer DUT contact arm 257 than the DUT contact arm of socket probes 300e-n. These varying lengths of DUT contact arm 257 allow for simultaneous testing of DUT pads 710a-n of varying heights.

### Preferred Embodiment

Referring to the dimensions shown in FIGS. 16 and 17, a preferred embodiment may use the following dimensions. FIG. 16 illustrates the key dimensions for the upper portion of an exemplary socketed probe. FIG. 17 illustrates the key dimensions for the lower portion of an exemplary socketed probe.

Dimension 1601 may be 1,112 μm, measured from the straight edge of cantilever arm 210 to the inflection point on the arm. Dimension 1602 measures from the straight edge of the cantilever arm 210 to the center of the PCB contact point 205 and is 707 μm. Dimension 1604, the width of PCB contact arm 207, is 125 μm. Cantilever arm 210 has three dimensions for thickness, 1603, 1605, and 1611 respectively. Dimension 1603 is 100 μm, dimension 1605 is 950 μm, and dimension 1611 is 109 μm.

Dimension 1606, which is the height of horizontal support arm 225, is 200 μm.

Dimension 1610, which is the height of rough positioning tab 230, is 942 μm. Dimension 1609, which is he width of rough positioning tab 230, is 200 μm. Fine positioning tab 240 has an overall width 1608 of 530 μm and a height 1607 of 467 μm.

As shown in FIG. 17, or the lower portion of a socketed probe 200, the lower handling tab 290 has a width 1701 of 350 μm and a height 1702 of 400 μm. Dimension 1703, which is the height of lower horizontal support art 275a, is 63 μm. Dimension 1704, which is the height of lower horizontal support art 275b, is 50 μm. Angle 1711, which is the angle between lower horizontal support arm 275a and DUT contact arm 257, may be 271°. This angle facilitates and tunes the behavior of DUT contact 255 to “scrub” DUT 700 as needed. Dimension 1705, which is the width of DUT contact arm 257, is 96 μm.

Lower positioning tab 270 has an overall width 1707 of 1,290 has a width 1705 of 0.096 μm. Fine positioning spring arm 272 has a width 1708 of 70 has a width 1705 of 0.096 μm. Positioning tab 270 has a width 1709 of 1,120 μm and a height 1710 of 650 μm. DUT contact point arm 257 has a width 1705 of 96.

The distance 1706 from the left edge of lower positioning tab 270 to the right edge of DUT contact arm 257 2,373 μm.

The overall height for a socket probe 200 is to be tall enough to accommodate both an upper and lower guide plates, 110 and 120 respectively, which are held in position by spacer 130. Because spacers may vary by testing needs, no exemplary dimension is provided for the preferred embodiment described above in conjunction with FIGS. 16 and 17.

### Guide Plates

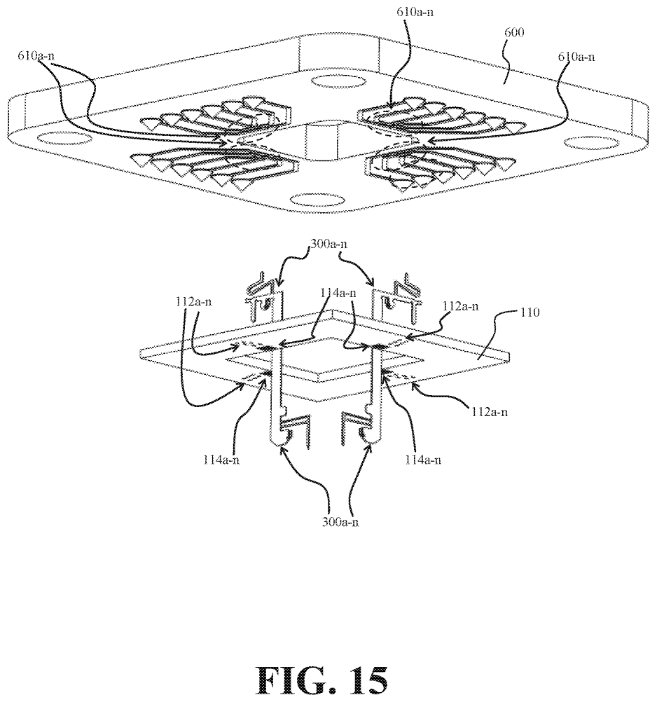

FIG. 15 shows an exemplary testing PCB 600 and an an exemplary upper guide plate 110 that is designed/configured for testing PCB 600.

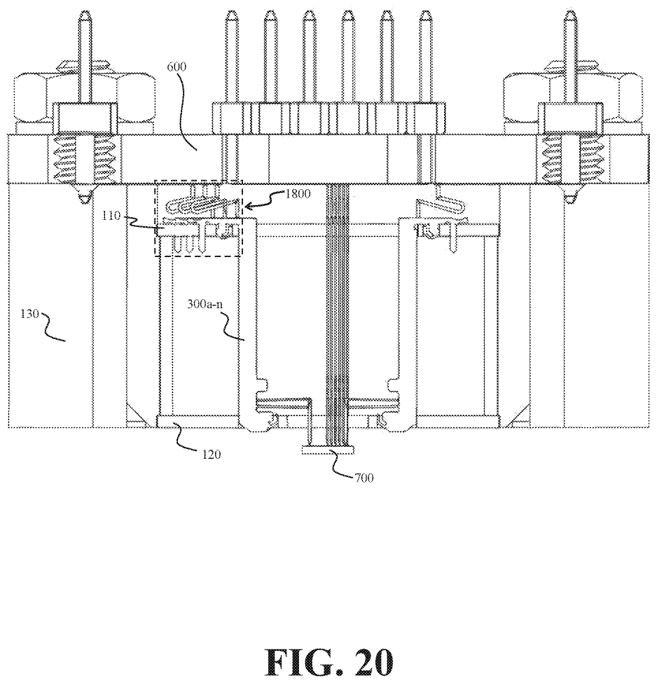

FIG. 20 shows an exemplary DUT 700 and an exemplary lower guide plate 120 that is designed/configured for DUT 700.

In general, many configurations and specifications exist or may be used for a DUT 700 and/or testing PCB 600. Guide plates and socketed probes may be adjusted, modified, configured, and/or designed for the various configurations of DUTs 700 and/or testing PCBs 600.

Guide plates may be made out of various materials or combinations of materials as are known in the art. In general, materials for guide plates may have several characteristics: non-electrically-conductive; substantially rigid; and/or amenable to material removeable, e.g., for forming slots as described herein. Exemplary materials for guide plates may include, but are not limited to, Photoveel, Photoveel II, Photoveel II-s, macerite, macor, PEEK, Silicon nitride, vespel, or glass. In one embodiment, silicon nitride may be used.

Guide plates, including the slots described herein, may be fabricated using various technologies and processes known in the art, e.g., etching, laser cutting, or mechanically machining with solid round cutting tools. Multiple guide plates may be combined if required.

### Dimensions and Sizes

In one embodiment, a socketed probe may have the dimensions as previously described shown in FIGS. 16 and 17. In some embodiments, a socketed probe may be available in varying horizontal offsets to facilitate space transformation patterns as shown, e.g., in FIG. 20.

### Other Views

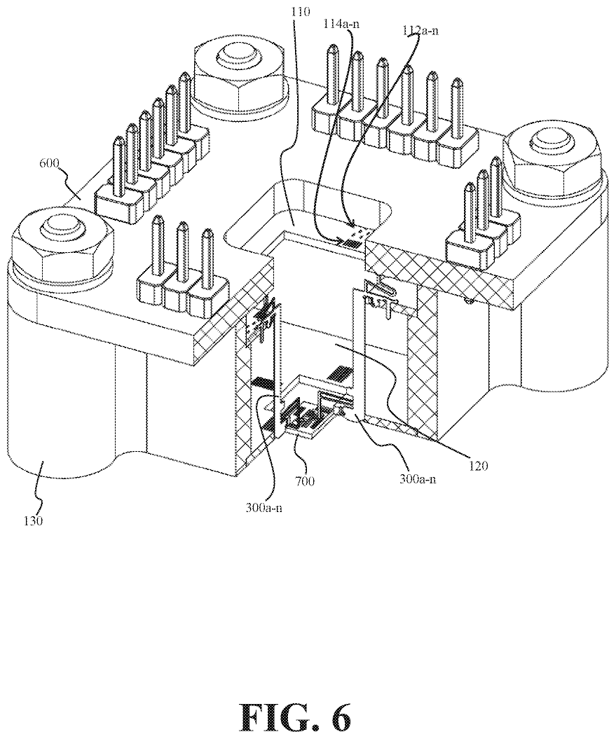

FIGS. 6-15 show various views and angles of space transformer system 100 as described herein.

FIG. 6 shows an upper elevated sectional view of space transformer system 100 having a one-quarter cutaway.

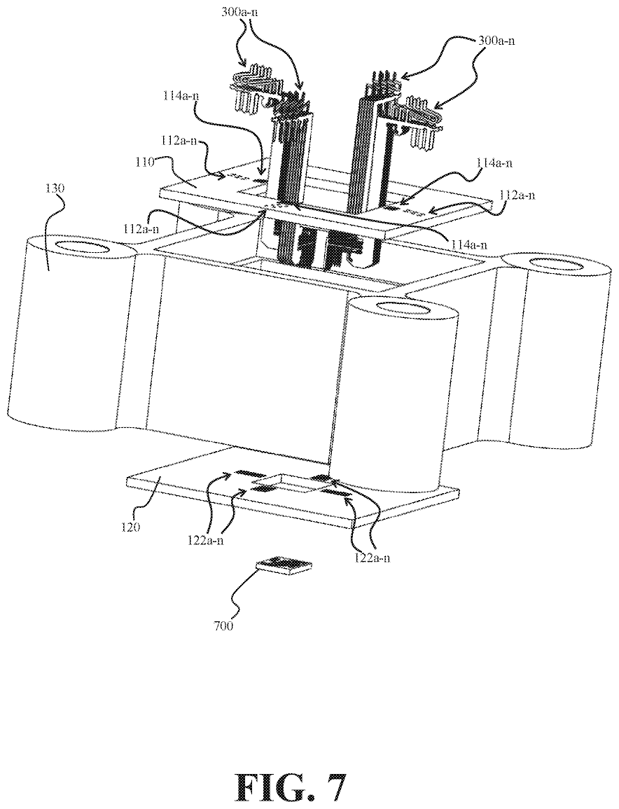

FIG. 7 shows an upper elevated exploded view of space transformer system 100 without testing PCB 600.

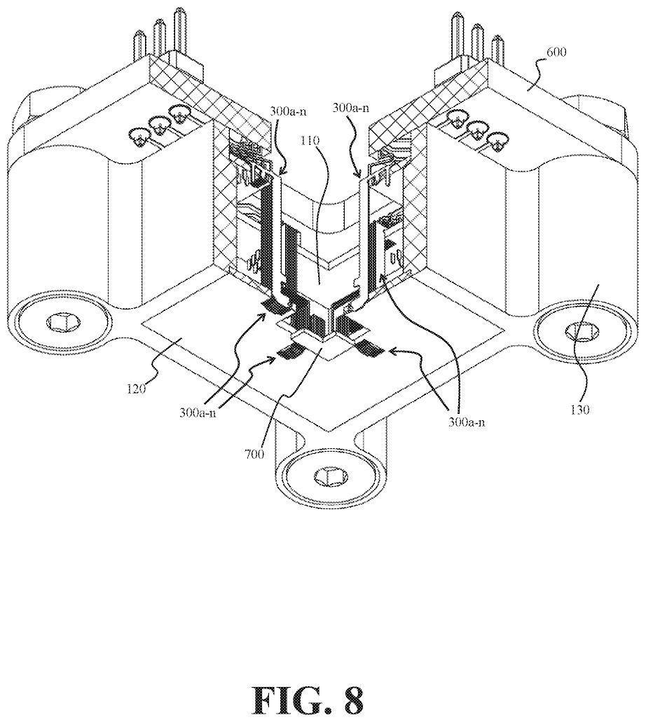

FIG. 8 shows a lower sectional view of space transformer system 100 having a one-quarter cutaway.

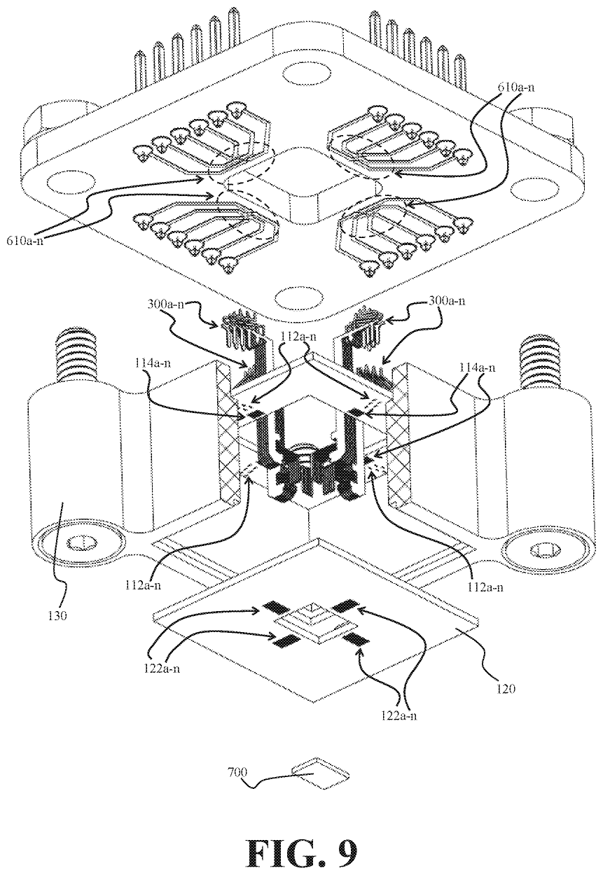

FIG. 9 shows an exploded lower angle view of space transformer system 100 having a one-quarter cutaway of spacer 130.

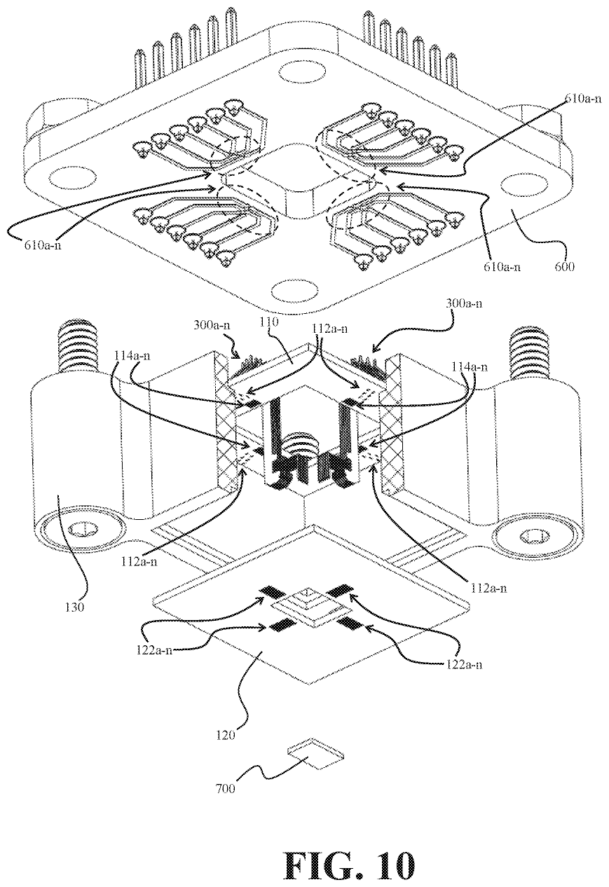

FIG. 10 shows an exploded lower angle view of space transformer system 100 having a one-quarter cutaway of spacer 130 and with two sides of socketed probes omitted)

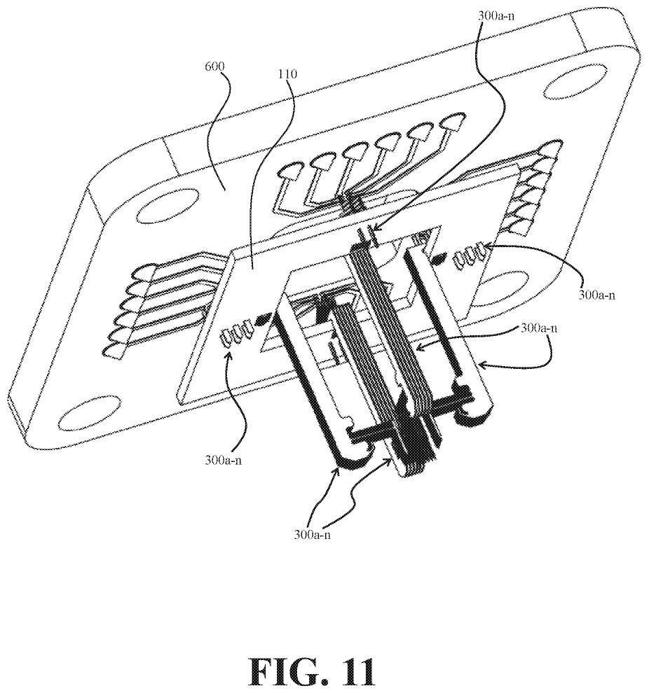

FIG. 11 shows a lower angle view of space transformer system 100 without some parts of the lower guide plate and without the DUT.

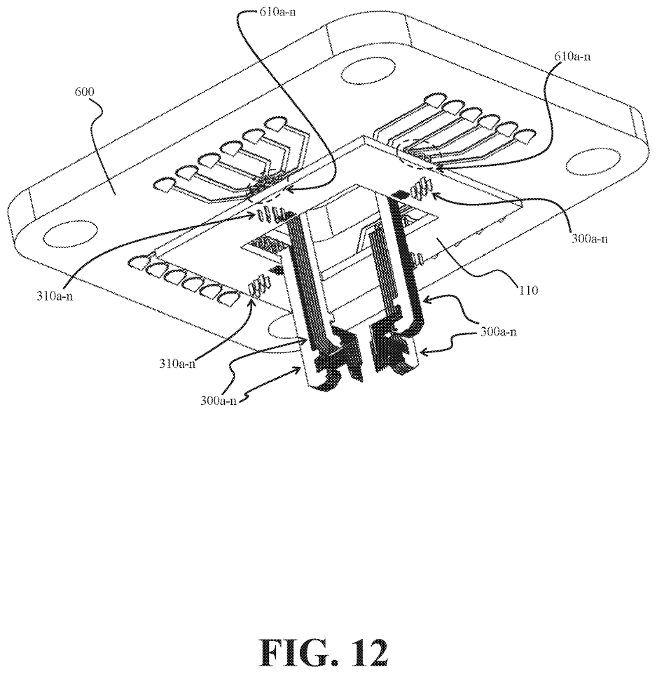

FIG. 12 shows a lower angle view of space transformer system 100 without some parts of the lower guide plate and without the DUT.

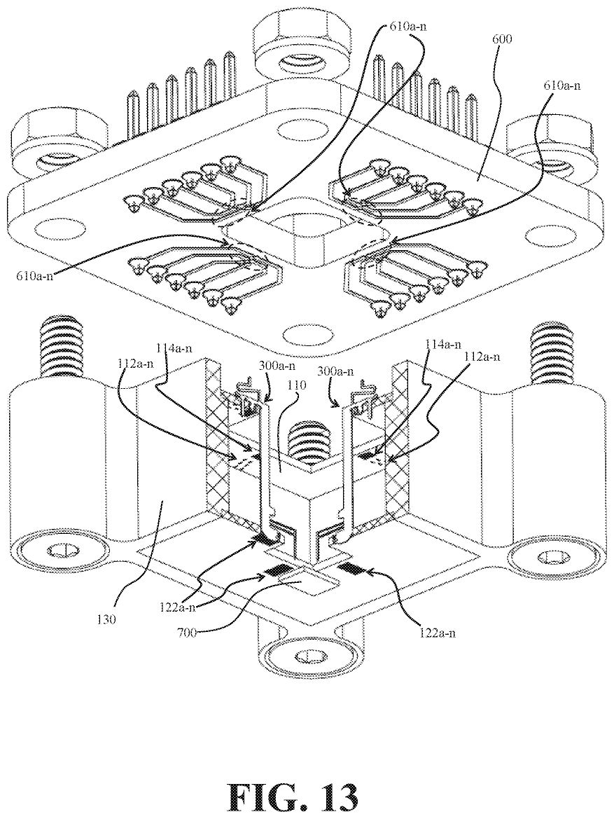

FIG. 13 shows an exploded lower angle view of space transformer system 100 with a one-quarter cutaway of the assembly comprising the lower guide plate, spacer, upper guide plate, and associated socketed probes.

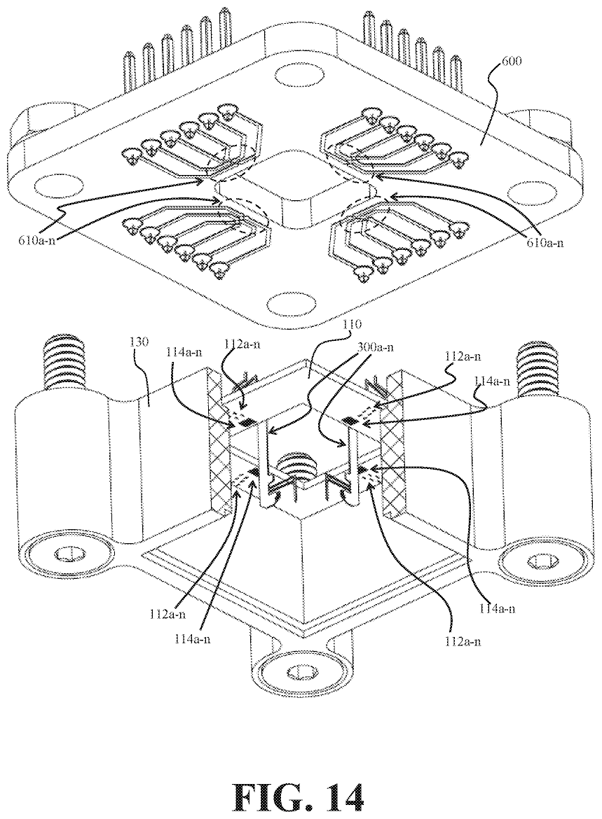

FIG. 14 shows an exploded lower angle view of space transformer system 100 with a one-quarter cutaway of the assembly comprising the lower guide plate, spacer, upper guide plate, and associated socketed probes-except for the upper guide plate, and having only two socketed probes.

FIG. 15 shows an exploded lower angle view of space transformer system 100 without the lower guide plate and DUT, and having only two socketed probes.

### Split Probe Embodiment

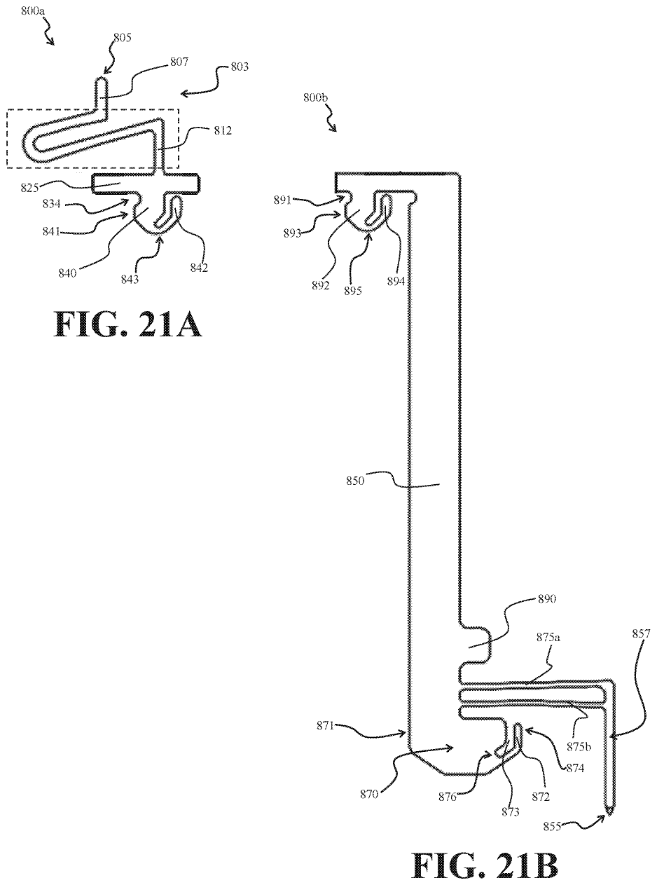

In one alternative embodiment, a socketed probe may be divided into two core components 800a and 800b as shown in FIGS. 21A and 21B. Core component 800a may comprise elements 803, 805, 807, 810, 812, 825, 834, 840, 841, 842, and 843, which may be analogous to components 203, 205, 207, 210, 212, 225, 234, 240, 241, 242, and 243, respectively in socketed probe 200—as described herein above.

Core component 800b may comprise elements 855, 857, 870, 875a, 875b, 890, 891, 892, 893, 894, and 895 which may be analogous to components 255, 257, 270, 275a, 275b, 290, 234, 240, 241, 242, and 243, respectively, in socketed probe 200—as described herein above.

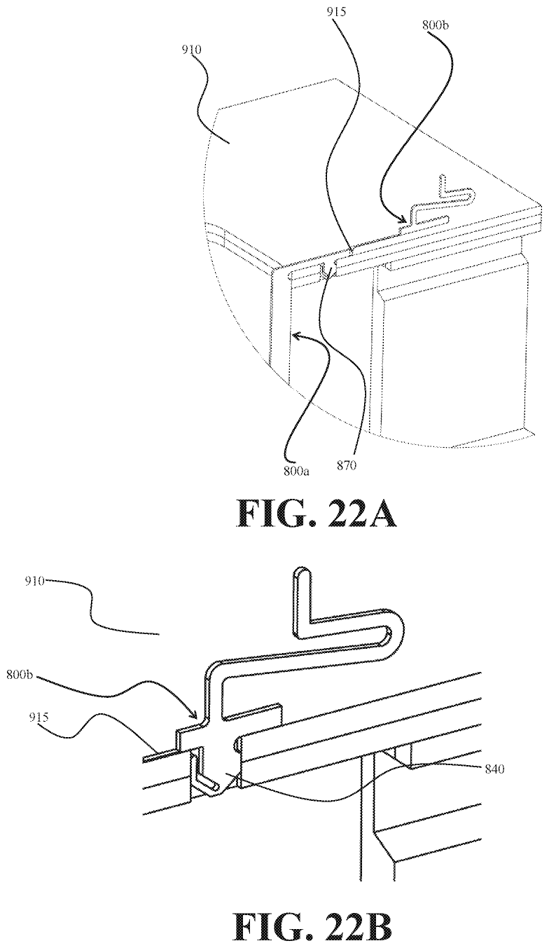

Because core components 800a and 800b are separate, they are electrically connected through a trace 915 on upper guide plate 910, as shown in FIGS. 22A-B. In one embodiment, this trace 915 may run from the wall of the slot in which tab 840 is seated in upper guide plate 910, along (or inside) upper guide plate 910, and to the wall of the slot in which tab 892 is seated in upper guide plate 910. FIG. 22A shows a cutaway cross section in which tab 870 is visible seated in a slot in upper guide plate 910. Because trace 915 “jogs,” tab 840 is not visible in the cutaway cross section of FIG. 22A. FIG. 22B shows another cutaway cross section in which tab 840 is visible seated in a slot in upper guide plate 910.

Although FIGS. 22A-B show trace 915 running into the slots in upper guide plate in which tabs 870 and 840 are seated, trace 915 could also be designed to contact other parts of core components 800a and 800b.

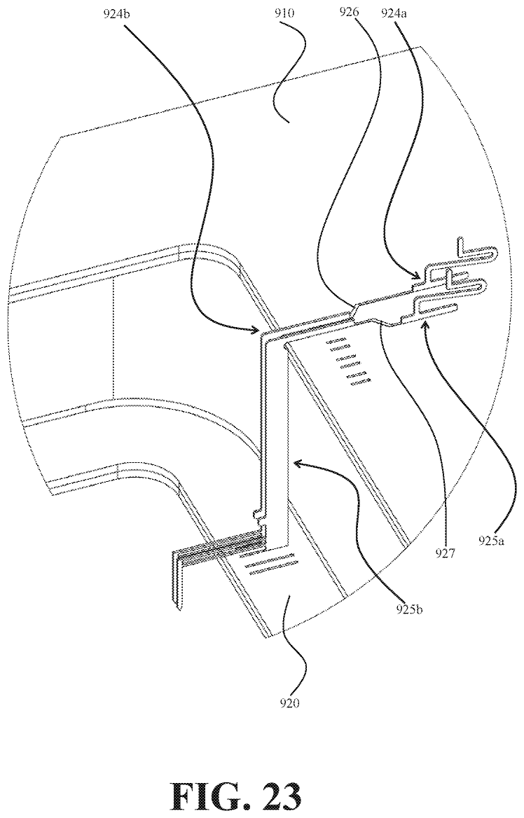

FIG. 23 shows an example in which two split probes 924a-b and 925a-b (i.e., similar to split probe 800a-b), are seated in slots in upper guide plate 910 and lower guide plate 920. As shown in FIG. 23, (i) core component 924a is connected to core component 924b via trace 926 in/on upper guide plate 910 and (ii) core component 925a is connected to core component 925b via trace 927 in/on upper guide plate 910.

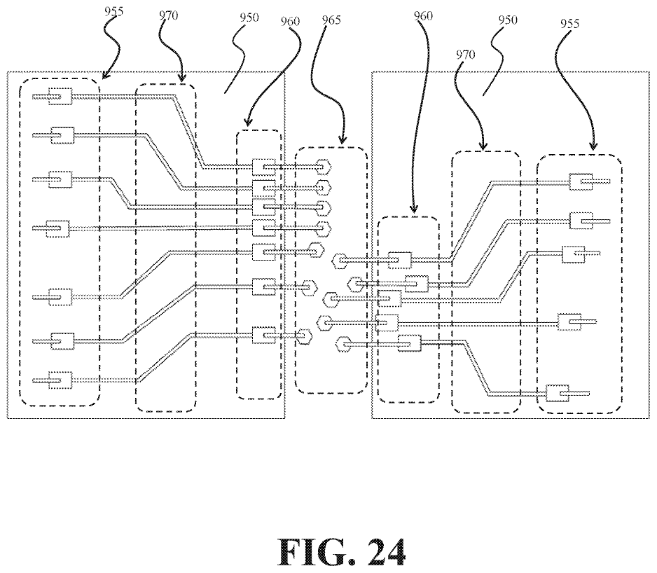

FIG. 24 shows a top-down view of an exemplary implementation using twelve (12) split probes as described herein. FIG. 24 shows seven split probes on the left and five split probes on the right, and shows the traces between the two components of the respective probes fanning out and routing the electrical signals to a larger pitch. FIG. 24 shows upper guide plates 950, “fanned-out” parts 955 of split probes in upper guide plates 950, non-“fanned-out” parts 960 of split probes in upper guide plates 950, parts 965 of probes in lower guide plate, and traces 970.

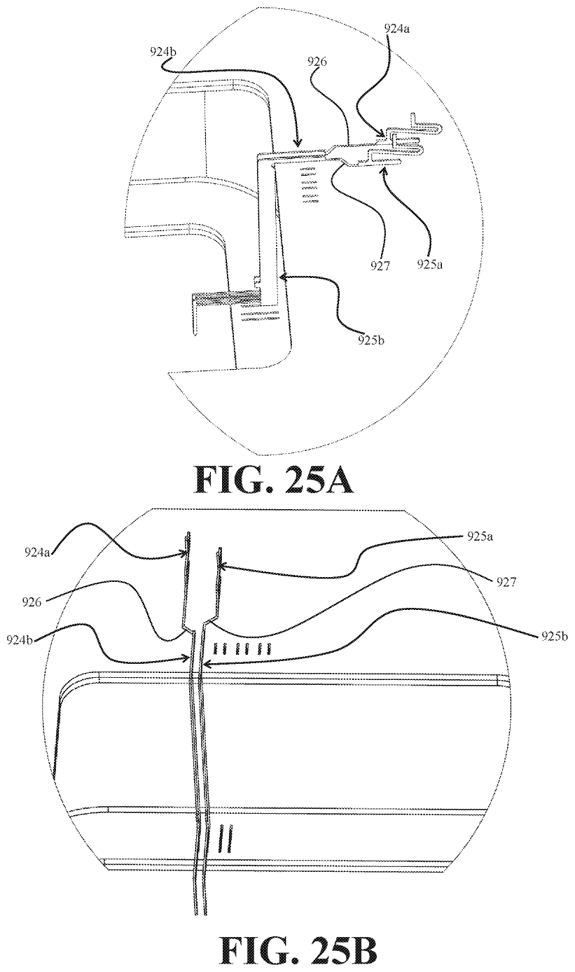

FIGS. 25A and 25B show two different views of the same implementation using two split probes as described herein. FIG. 25A an elevated angle view. FIG. 25B shows a top-down view. FIGS. 25A-B show the traces rerouting/fanning out the signals between the two components of the respective split probes.

As shown in FIGS. 21A-25B use of split probes allows for use of identical core components (e.g., 800a for the component seated in the lower guide plate for all probes; and 800b for the component seated in the upper guide plate for all probes) regardless of the space transformation pattern (i.e., “fanning out” or “routing”) because the unique routing is accomplished through traces on the upper guide plate instead of using probes with varying routing features. Additionally, use of traces for makes it easier to reroute in two dimensions because it is easier for a trace to route in two dimensions that to manufacture and install a probe that reroutes (i.e., does space transformation) in two dimensions.

### Additional Embodiment

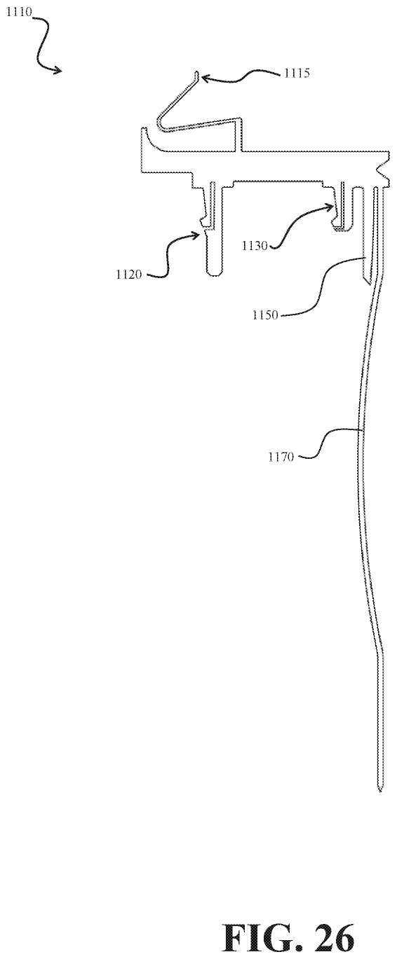

As shown in FIGS. 26-34, an additional alternative embodiment may comprise space transformer system 1100.

Space transformer system 1100 is similar to space transformer system 100, with several distinctions.

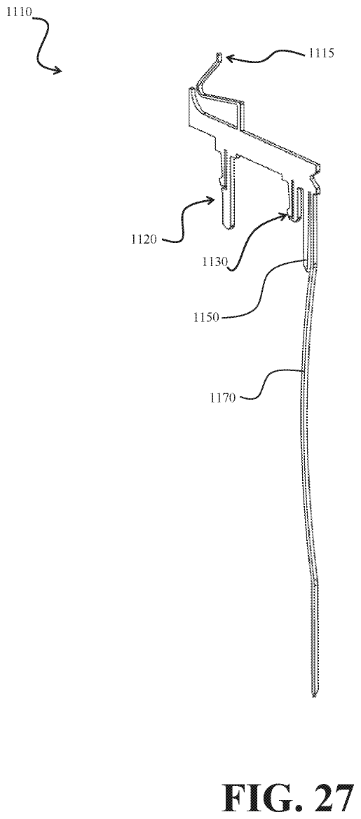

FIGS. 26 and 27 show an exemplary design and exemplary dimensions for a probe 1110 comprising PCB contact 1115, upper first positioning tab 1120, upper second positioning tab 1130, DUT probe guard 1150, and DUT probe arm 1170.

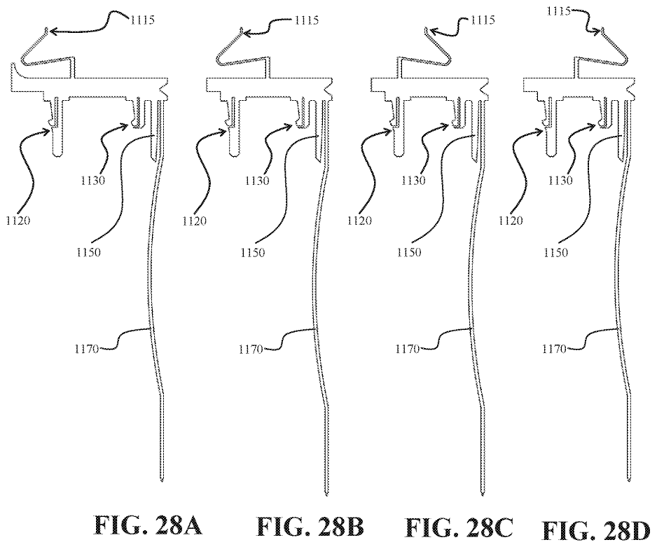

FIGS. 28A-D shows four variations of this design in which the distal end offset is different in each variant.

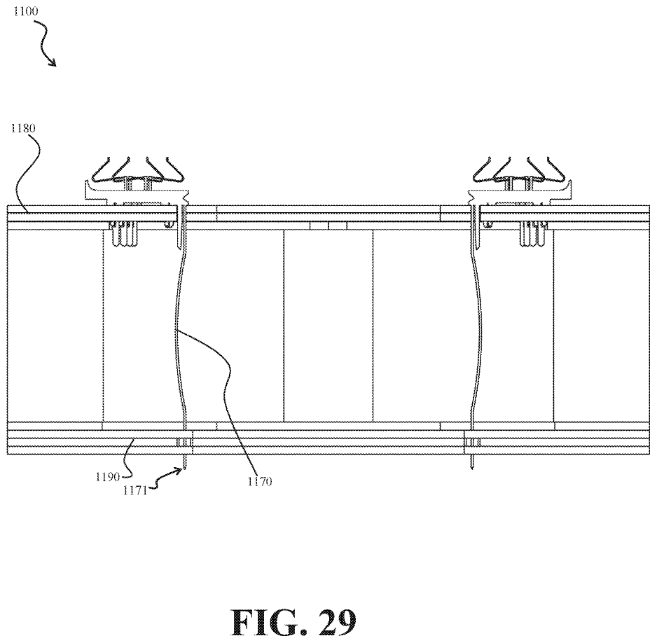

FIG. 29 shows a side cross section view of an exemplary implementation-including upper guide plate 1180 and lower guide plate 1190—using eight probes (e.g., the probes in FIGS. 26, 27, and 28A-D), wherein each of the eight probes has one of four distal end offset variations as shown in FIGS. 28A-D.

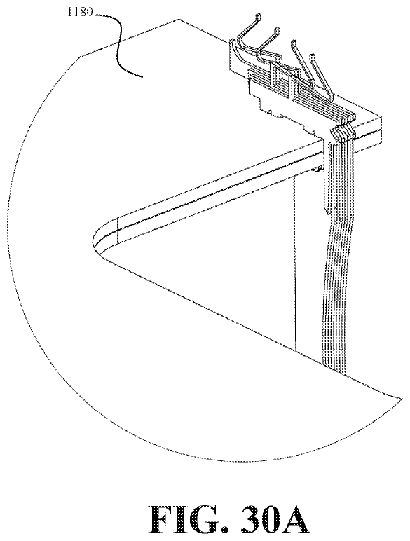

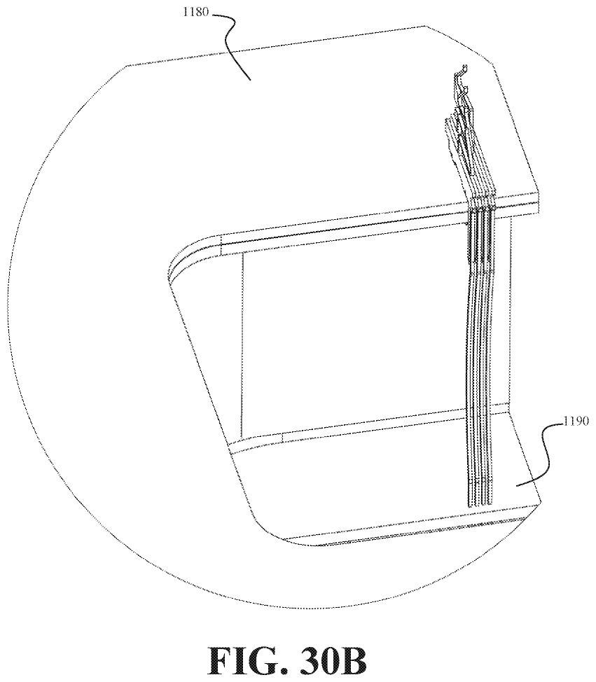

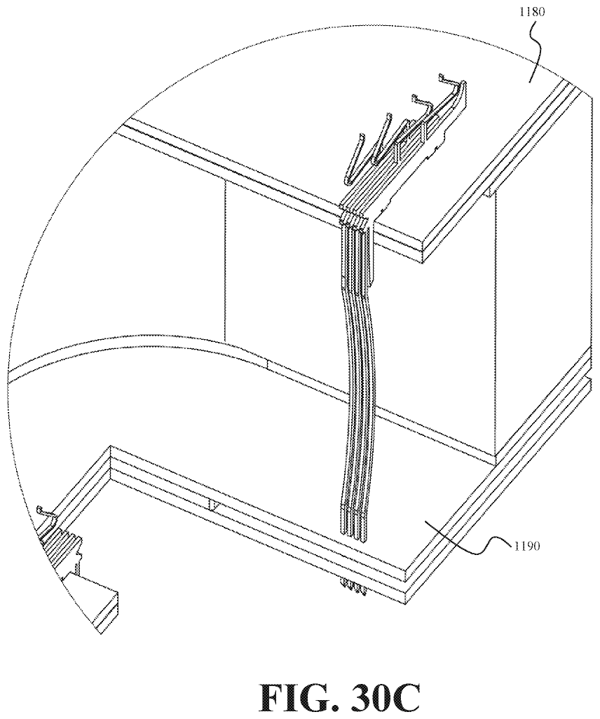

FIGS. 30A-C shows how four probes (e.g, the probes in FIGS. 28A-D), each having a different distal end offset, might be located in an upper guide plate in an exemplary implementation.

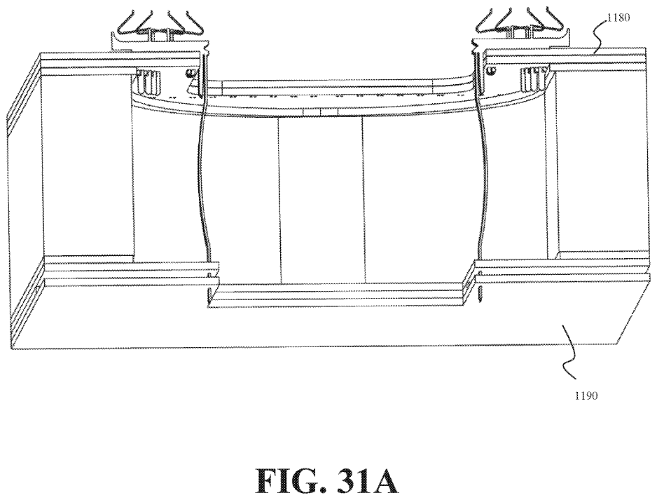

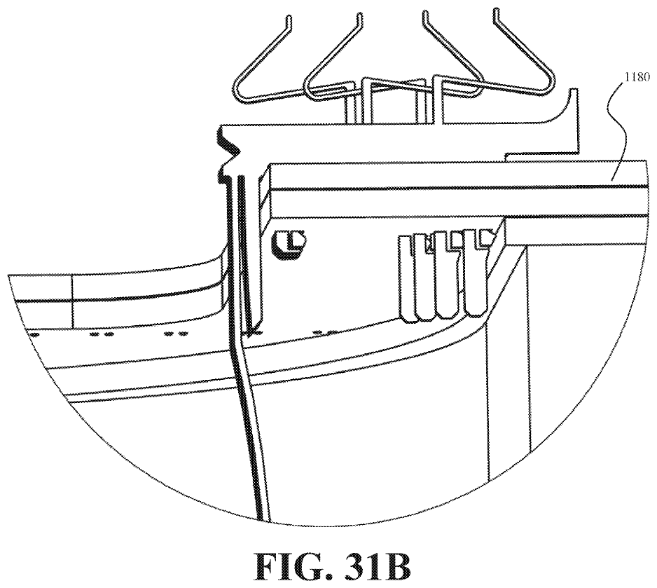

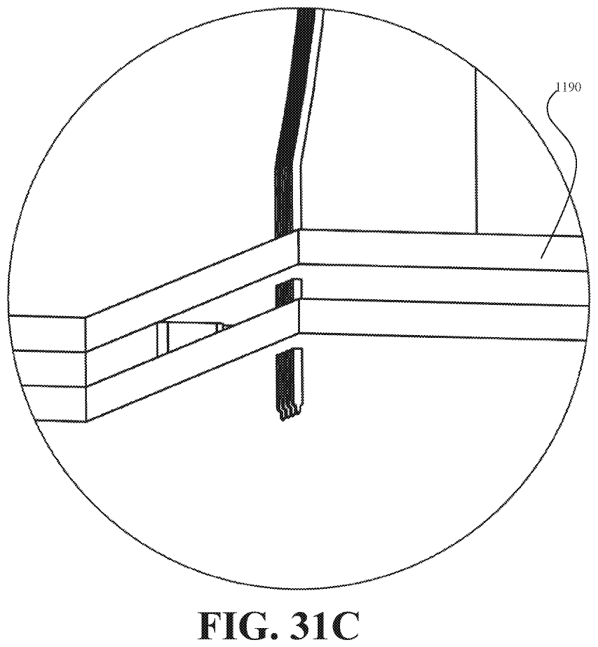

FIGS. 31A-C show additional views of an exemplary implementation of the probes shown in FIGS. 26, 27, and 28A-D.

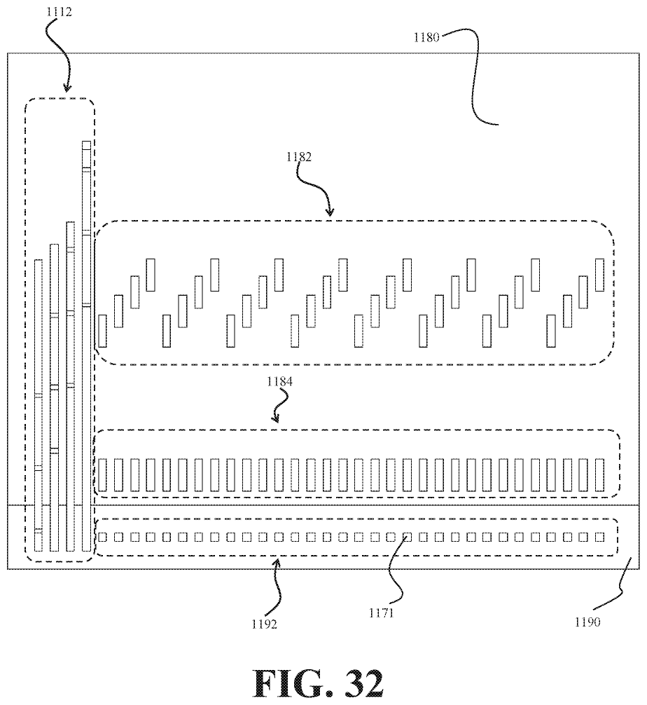

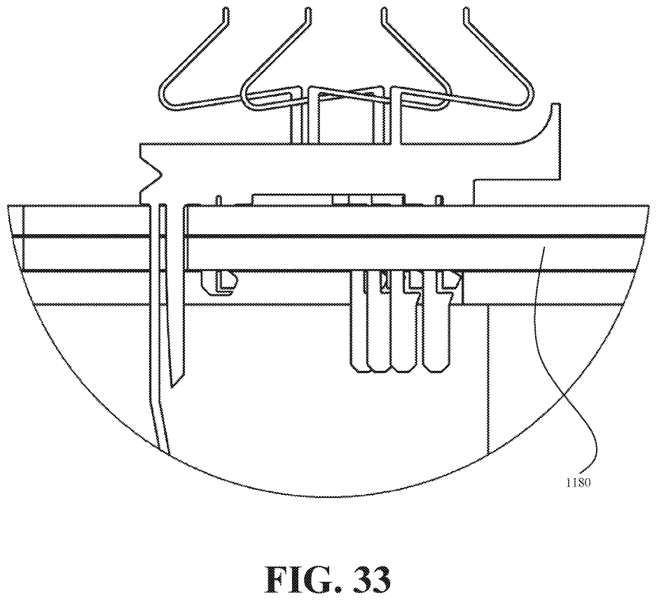

FIG. 32 shows a top-down view of upper guide plate holes 1182 for upper first positioning tabs (1120), upper guide plate holes 1184 for upper second positioning tabs (1130), and lower guide plate holes 1192 for DUT probe arms (1170) in an exemplary embodiment. As shown in FIG. 32, probes 1112 may be probes such as those shown in FIGS. 26, 27, and 28A-D.

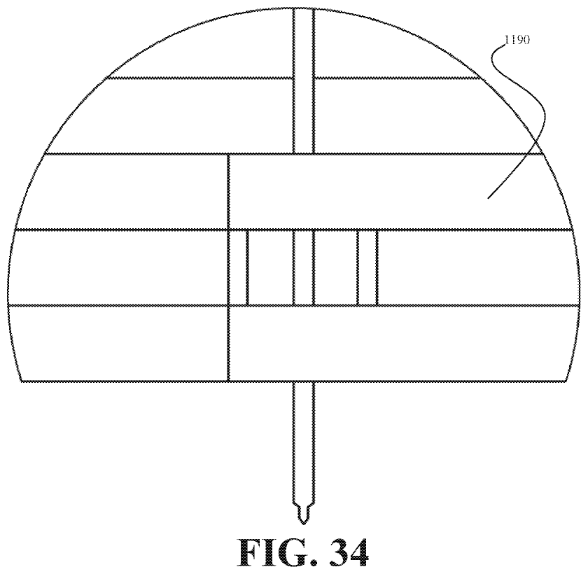

FIG. 33 shows a close-up side view of four probes (e.g., the probes shown in FIGS. 26, 27, and 28A-D), each having different distal offsets, seated in upper guide plate 1180.

FIG. 34 shows a close-up side view of four probes (e.g., the probes shown in FIGS. 26, 27, and 28A-D) seated in lower guide plate 1190.

As shown in FIGS. 26-34, probe 1110 is similar to the probes described herein above, but also has several distinct features.

Probe 1110 may comprise an upper first positioning tab 1120, an upper second positioning tab 1130, probe guard 1150, DUT probe arm 1170. Similar to fine positioning tab 240, upper first positioning tab 1120 and upper second positioning tab 1130 may each comprise a spring element to ensure that the non-spring side of the tab is flush with the associate wall of the slot in upper guide plate 1180 into which the respective tabs are inserted/seated. Probe guard 1150 protects the fragile DUT probe arm 1170 from damage when probe 1110 (specifically, tabs 1120 and 1130) is being inserted by a human operator or otherwise into upper guide plate 1180 because an imperfect insertion may result in potentially bumping (and possibly damaging) DUT probe arm 1170 into upper guide plate 1180. Probe guard 1150 is not absolutely necessary, but as a practical matter may prevent damage to DUT probe arm 1170.

As shown in FIGS. 26-34, DUT probe arm 1170 may comprise a curved section. The curved section allows for a controlled spring deflection when DUT probe arm 1170 is inserted through a hole in lower guide plate 1190 and comes into contact with a target DUT pad. When pressed into the DUT pad, DUT probe arm 1170 deflects to press the bottom tip of DUT probe arm 1170 into the DUT pad. The curvature is designed to result in a controlled spring deflection, i.e., a predictable spring deflection such that multiple DUT probe arms in close proximity will not contact each other (which would cause a short circuit) when compressed and deflected.

Many geometries may be used to accomplish the desired springlike-compression and depression. The curvature shown is one such exemplary geometry.

As shown in FIGS. 26-34, probe 1110 comprises two positioning tabs 1120 and 1130 for insertion into corresponding slots in upper guide plate 1180. Although it may be possible to use only one positioning tab, such a design may result in too much undesirable rotational play in probe 1110—but using two tabs, sufficiently spaced from each other, may minimize such play. As shown in FIGS. 26-34, Tabs 1120 and 1130 are different lengths so that they enter upper guide plate 1180 separately and do not require simultaneous correct positioning of the two tabs 1120 and 1130. The lengths (up-down/vertical length as shown in FIGS. 26-34) of tab 1120, tab 1130, and DUT probe arm 1170 are designed such that these three elements all enter their respective slots/holes (slot in upper guide plate 1180 for tab 1120; slot in upper guide plate 1180 for tab 1130; slot/hole in lower guide plate 1190 for DUT probe arm 1170) at different times as probe 1110 is being seated/inserted into upper guide plate 1180 and lower guide plate 1190 from above (or substantially) above as shown in FIGS. 26-34. This avoids the need to simultaneously correctly position tab 1120, tab 1130, and DUT probe arm 1170. In one embodiment, the vertical (as shown in FIG. 28) lengths of tab 1120, tab 1180 and DUT probe arm 1170 are designed such that tab 1120 goes into upper guide plate 1180 first, then DUT probe arm 1170 goes into lower guide plate 1190, and then tab 1130 goes into upper guide plate 1180.

Additionally, use of two tabs 1120 and 1130 may result in a more stable seating of probe 1110 in upper guide plate 1180.

As shown in FIGS. 26-34, lower guide plate 1190 has a hole 1171 for DUT probe arm 1170. This hole 1171 is located to guide DUT probe arm 1170 so that, when lowered into place in upper guide plate 1180 and lower guide plate 1190, DUT probe arm 1170 contacts the target DUT probe.

In one embodiment, as shown in FIGS. 28A-33, the relative locations of tabs 1120 and 1130 may vary based on location of the upper (PCB) contact 1115 on probe 1110. FIGS. 28A-D show four variants of probe 1110. In each variant tab 1130 remains in a fixed location, but PCB contact 115 and tab 1120 are in different locations along the x axis (as shown in FIGS. 28A-D). The varying locations of PCB contact 1115 allows for space transformation (from tight pitch of DUT to larger pitch of testing PCB). Varying the location of tab 1120 allows for varying the location of the corresponding slot in upper guide plate 1180 so that the correct probe variant must be placed at each slot location upper guide plate 1180—because tab 1120 for the incorrect probe variant will not align with the corresponding slot in upper guide plate 1180.

In one embodiment, after inserting one or more probes 1110 into lower guide plate 1190, lower guide plate 1190 may be shifted slightly to the right or to the left (as shown in FIGS. 29 and 34) to avoid play or uncertainty that may occur because the probes may not all be touching the same wall (left or right) of their respective corresponding slots in lower guide plate 1190, or may not be touching either wall—which may result in unacceptable play or movement in the probes. By slightly shifting lower guide plate 1190 to the left or to the right, it is possible to be certain that all probes are touching the same wall (i.e., left wall or right wall) of the hole/slot in lower guide plate 1190 corresponding to each respective probe.

The dimensions and relative dimensions of the probes and systems disclosed herein may be changed and scaled and remain with the description and invention disclosed herein.

1. A socketed probe, comprising:
an upper assembly;
a lower assembly; and
a connector arm connecting the upper assembly to the lower assembly;
wherein:
the upper assembly comprises:
an upper horizontal support arm;
a contact support arm;
a cantilever spring arm;
a contact point arm;
a contact configured to be displaced in an upper assembly contact principal displacement direction through planar compression of the cantilever spring arm; and
an upper support arm fine positioning tab;
the lower assembly comprises:
a lower horizontal support arm;
a contact point arm;
a contact; and
a lower support arm fine positioning tab;
the upper support arm fine positioning tab is configured to be inserted into a slot such that the insertion movement is parallel to the upper assembly contact principal displacement direction;
the lower support arm fine positioning tab is configured to be inserted into a slot such that the insertion movement is parallel to the upper assembly contact principal displacement direction; and
the insertion movement of the upper support arm fine positioning tab is in the same direction as the insertion movement of the lower support arm fine positioning tab.

2. The socketed probe of claim 1, wherein at least one of the upper assembly and the lower assembly further comprises a rough positioning tab.

3. The socketed probe of claim 2, wherein the upper assembly comprises a rough positioning tab.

4. The socketed probe of claim 3, wherein the rough positioning tab extends further from the upper horizontal support arm than the upper support arm fine positioning tab.

5. The socketed probe of claim 1, wherein the upper support fine positioning tab comprises a spring arm.

6. The socketed probe of claim 1, wherein the lower support arm fine positioning tab comprises a spring arm.

7. The socketed probe of claim 1, wherein the upper assembly comprises a handling tab.

8. The socketed probe of claim 1, wherein the lower assembly comprises a handling tab.

9. The socketed probe of claim 1, wherein:
the lower horizontal support arm comprises a first lower support sub-arm and a second lower support sub-arm;
the first lower support sub-arm and the second lower support sub-arm are substantially parallel to each other; and
one of the first lower support sub-arm and the second lower support sub-arm is substantially straight and the other of the first lower support sub-arm and the second lower support sub-arm is slightly curved.

10. The socketed probe of claim 1, wherein:
the upper assembly comprises a rough positioning tab;
the rough positioning tab extends further from the upper horizontal support arm than the upper support arm fine positioning tab;
the upper support fine positioning tab comprises a spring arm;
the upper assembly comprises an upper handling tab;
the lower assembly comprises a lower handling tab;
the lower horizontal support arm comprises a first lower support sub-arm and a second lower support sub-arm;
the first lower support sub-arm and the second lower support sub-arm are substantially parallel to each other; and
one of the first lower support sub-arm and the second lower support sub-arm is substantially straight and the other of the first lower support sub-arm and the second lower support sub-arm is slightly curved.

11. A socketed probe system, comprising:
an upper guide plate;
a lower guide plate;
a spacer; and
a socketed probe;
wherein:
the socketed probe comprises an upper assembly, a lower assembly, and a connector arm connecting the upper assembly to the lower assembly;
the upper assembly comprises:
an upper horizontal support arm;
a contact support arm;
a cantilever spring arm;
a contact point arm;
a contact configured to be displaced in an upper assembly contact principal displacement direction through planar compression of the cantilever spring arm; and
an upper support arm fine positioning tab;
the lower assembly comprises:
a lower horizontal support arm;
a contact point arm;
a contact; and
a lower support arm fine positioning tab;
the upper support arm fine positioning tab is configured to be inserted into an upper guide plate slot such that the insertion movement is parallel to the upper assembly contact principal displacement direction;
the lower support arm fine positioning tab is configured to be inserted into a slot such that the insertion movement is parallel to the upper assembly contact principal displacement direction;
the insertion movement of the upper support arm fine positioning tab is in the same direction as the insertion movement of the lower support arm fine positioning tab;
the upper guide plate comprises the upper guide plate slot dimensioned for insertion of the upper support arm fine positioning tab;
the lower guide plate comprises a slot dimensioned for insertion of the lower support arm fine positioning tab;
the upper guide plate and the lower guide plate are substantially parallel to each other; and
the spacer is configured to maintain a constant distance between the upper guide plate and the lower guide plate.

12. The socketed probe system of claim 11, wherein at least one of the upper assembly and the lower assembly further comprises a rough positioning tab.

13. The socketed probe system of claim 12, wherein the upper assembly comprises a rough positioning tab.

14. The socketed probe system of claim 13, wherein the rough positioning tab extends further from the upper horizontal support arm than the upper support arm fine positioning tab.

15. The socketed probe system of claim 11, wherein the upper support fine positioning tab comprises a spring arm.

16. The socketed probe system of claim 11, wherein the lower support arm fine positioning tab comprises a spring arm.

17. The socketed probe system of claim 11, wherein the upper assembly comprises a handling tab.

18. The socketed probe system of claim 11, wherein the lower assembly comprises a handling tab.

19. The socketed probe system of claim 11, wherein:
the lower horizontal support arm comprises a first lower support sub-arm and a second lower support sub-arm;
the first lower support sub-arm and the second lower support sub-arm are substantially parallel to each other; and
one of the first lower support sub-arm and the second lower support sub-arm is substantially straight and the other of the first lower support sub-arm and the second lower support sub-arm is slightly curved.

20. The socketed probe system of claim 11, wherein:
the upper assembly comprises a rough positioning tab;
the rough positioning tab extends further from the upper horizontal support arm than the upper support arm fine positioning tab;
the upper support fine positioning tab comprises a spring arm;
the upper assembly comprises an upper handling tab;
the lower assembly comprises a lower handling tab;
the lower horizontal support arm comprises a first lower support sub-arm and a second lower support sub-arm;
the first lower support sub-arm and the second lower support sub-arm are substantially parallel to each other; and
one of the first lower support sub-arm and the second lower support sub-arm is substantially straight and the other of the first lower support sub-arm and the second lower support sub-arm is slightly curved.
